(19) United States
(12) Patent Application Publication
(10) Pub. No.: US 2025/0159861 A1
(43) Pub. Date: May 15, 2025

(54) THREE-DIMENSIONAL SEMICONDUCTOR DEVICES

(71) Applicant: SAMSUNG ELECTRONICS CO., LTD., SUWON-SI, GYEONGGI-DO (KR)

(72) Inventors: Keonhee Park, Suwon-si (KR); Haewook Jeong, Suwon-si (KR)

(21) Appl. No.: 18/825,173

(22) Filed: Sep. 5, 2024

(30) Foreign Application Priority Data
Nov. 9, 2023 (KR) 10-2023-0154185

(51) Int. Cl. H10B 12/00

(52) U.S. Cl. CPC H10B 12/00

(57) ABSTRACT

A semiconductor device includes first and second bit lines, a word line, first and second channels and a capacitor. The first and second bit lines extend primarily in a first direction and are spaced apart from each other in a second direction on a substrate. The word line includes first extension portions extending primarily in a third direction, between the first and second bit lines, and a second extension portion extending primarily in the second direction at the same level as the first extension portions and is connected thereto. Each of the first and second channels extends through the first extension portions. The capacitor includes a first capacitor electrode electrically connected to the first channel, a dielectric pattern disposed on a surface of the first capacitor electrode, and a second capacitor electrode disposed on a surface of the dielectric pattern and electrically connected to the second channel.

### CROSS-REFERENCE TO RELATED APPLICATION

This application claims priority under 35 U.S.C. § 119 to Korean Patent Application No. 10-2023-0154185, filed on Nov. 9, 2023 in the Korean Intellectual Property Office, the disclosure of which is hereby incorporated by reference in its entirety.

### TECHNICAL FIELD

The present disclosure relates to a semiconductor device and, more particularly, to a three-dimensional DRAM device.

### DISCUSSION OF RELATED ART

Dynamic random-access memory (DRAM) are a type of volatile memory used to store data for active use or processing. Unlike static random-access memory (RAM), DRAM stores each bit of data in a separate capacitor. DRAM devices generally include word lines, bit lines, channels and capacitors, and in order to increase the integration degree of the DRAM device, a method of efficiently arranging the word lines, the bit lines, the channels and the capacitors is needed.

### SUMMARY

A semiconductor device includes first and second bit lines, a word line, first and second channels and a capacitor. The first and second bit lines are disposed on a substrate. Each of the first and second bit lines extends in a first direction that is substantially perpendicular to an upper surface of the substrate. The first and second bit lines are spaced apart from each other in a second direction that is substantially parallel to the upper surface of the substrate. The word line includes first extension portions and a second extension portion. The first extension portions are disposed between the first and second bit lines, and each of the first extension portions extend primarily in a third direction that is substantially parallel to the upper surface of the substrate and intersecting the second direction. The second extension portion extends in the second direction at the same level as the first extension portions and are connected to the first extension portions. Each of the first and second channels extends through the first extension portions of the word line. The capacitor includes a first capacitor electrode electrically connected to the first channel, a dielectric pattern disposed on a surface of the first capacitor electrode, and a second capacitor electrode disposed on a surface of the dielectric pattern and being electrically connected to the second channel.

A semiconductor device includes bit lines, a first transistor, a capacitor, a second transistor and a word line. The bit lines are disposed on a substrate, each of the bit lines extend primarily in a first direction, and the bit lines are spaced apart from each other in a second direction that is substantially perpendicular to the first direction. The first transistor, the capacitor and the second transistor are sequentially disposed in the second direction between the bit lines. The word line includes first extension portions and a second extension portion. The first extension portions are electrically connected to the first and second transistor, respectively, and each of the first extension portions extends in a third direction that is substantially perpendicular to the first and second directions. The second extension portion extends in the second direction and is connected to the first extension portions. Each of the first and second transistors includes a gate electrode electrically connected to each of the first extension portions of the word line, a channel electrically connected to the gate electrode, and first and second source/drain layers at opposite sides, respectively, of the channel in the second direction. The capacitor includes a first capacitor electrode, a dielectric pattern and a second capacitor electrode sequentially stacked. The first source/drain layers of the first and second transistors, respectively, is electrically connected to the bit lines, respectively, and the second source/drain layers of the first and second transistors, respectively, are electrically connected to the first and second capacitor electrodes, respectively.

A semiconductor device includes first and second bit lines, a word line, first and second channels, a first source/drain layer, a second source/drain layer, a capacitor, a third source/drain layer, a fourth source/drain layer, a connection pattern and insulation pattern. The first and second bit lines are disposed on a substrate, each of the first and second bit lines extend primarily in a first direction that is substantially perpendicular to an upper surface of the substrate, and the first and second bit lines are spaced apart from each other in a second direction that is substantially parallel to the upper surface of the substrate. The word line includes first extension portions and a second extension portion. The first extension portions are disposed between the first and second bit lines, and each of the first extension portions extends in a third direction that is substantially parallel to the upper surface of the substrate and intersecting the second direction. The second extension portion extends in the second direction at the same level as the first extension portions and is connected to the first extension portions. Each of the first and second channels extends through the first extension portions of the word line. The first source/drain layer is disposed between and contacts both the first bit line and the first channel. The second source/drain layer is disposed between and contacts both the second bit line and the second channel. The capacitor includes a first capacitor electrode contacting the first source/drain layer, a dielectric pattern disposed on a surface of the first capacitor electrode and a second capacitor electrode disposed on a surface of the dielectric pattern. The third source/drain layer is disposed between and contacts both the first channel and the first capacitor electrode. The fourth source/drain layer is disposed between the second channel and the second capacitor electrode. The connection pattern contacts both the second capacitor electrode and the second source/drain layer. The insulation pattern is disposed between the first capacitor electrode and the connection pattern.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is an equivalent circuit diagram illustrating a sub-cell array included in a cell array of a semiconductor device;

FIG. 2 is a graph illustrating a voltage change of a bit line included in the semiconductor device;

FIG. 3 is a perspective view illustrating a semiconductor device in accordance with example embodiments;

FIG. 4 is a plan view illustrating a semiconductor device in accordance with example embodiments;

FIG. 5 is a perspective view illustrating a semiconductor device in accordance with example embodiments;

FIG. 6 is a cross-sectional view illustrating a semiconductor device in accordance with example embodiments;

FIG. 7 is a cross-sectional view illustrating a semiconductor device in accordance with example embodiments;

FIG. 8 is a perspective view illustrating a method of manufacturing a semiconductor device in accordance with example embodiments;

FIG. 9 is a perspective view illustrating a method of manufacturing a semiconductor device in accordance with example embodiments;

FIG. 10 is a plan view illustrating a method of manufacturing a semiconductor device in accordance with example embodiments;

FIG. 11 is a perspective illustrating a method of manufacturing a semiconductor device in accordance with example embodiments;

FIG. 12 is a cross-sectional view illustrating a method of manufacturing a semiconductor device in accordance with example embodiments;

FIG. 13 is a perspective view illustrating a method of manufacturing a semiconductor device in accordance with example embodiments;

FIG. 14 is a cross-sectional view illustrating a method of manufacturing a semiconductor device in accordance with example embodiments;

FIG. 15 is a perspective view illustrating a method of manufacturing a semiconductor device in accordance with example embodiments;

FIG. 16 is a plan view illustrating a method of manufacturing a semiconductor device in accordance with example embodiments;

FIG. 17 is a perspective view illustrating a method of manufacturing a semiconductor device in accordance with example embodiments;

FIG. 18 is a plan view illustrating a method of manufacturing a semiconductor device in accordance with example embodiments;

FIG. 19 is a perspective view illustrating a method of manufacturing a semiconductor device in accordance with example embodiments;

FIG. 20 is a plan view illustrating a method of manufacturing a semiconductor device in accordance with example embodiments;

FIG. 21 is a cross-sectional view illustrating a method of manufacturing a semiconductor device in accordance with example embodiments;

FIG. 22 is a perspective view illustrating a method of manufacturing a semiconductor device in accordance with example embodiments;

FIG. 23 is a cross-sectional view illustrating a method of manufacturing a semiconductor device in accordance with example embodiments;

FIG. 24 is a cross-sectional view illustrating a method of manufacturing a semiconductor device in accordance with example embodiments;

FIG. 25 is a perspective view illustrating a method of manufacturing a semiconductor device in accordance with example embodiments;

FIG. 26 is a perspective view illustrating a method of manufacturing a semiconductor device in accordance with example embodiments;

FIG. 27 is a perspective view illustrating a method of manufacturing a semiconductor device in accordance with example embodiments;

FIG. 28 is a perspective view illustrating a method of manufacturing a semiconductor device in accordance with example embodiments;

FIG. 29 is a perspective view illustrating a method of manufacturing a semiconductor device in accordance with example embodiments;

FIG. 30 is a cross-sectional view illustrating a method of manufacturing a semiconductor device in accordance with example embodiments;

FIG. 31 is a perspective view illustrating a method of manufacturing a semiconductor device in accordance with example embodiments;

FIG. 32 is a cross-sectional view illustrating a method of manufacturing a semiconductor device in accordance with example embodiments;

FIG. 33 is a perspective view illustrating a method of manufacturing a semiconductor device in accordance with example embodiments;

FIG. 34 is a perspective view illustrating a method of manufacturing a semiconductor device in accordance with example embodiments;

FIG. 35 is a perspective view illustrating a method of manufacturing a semiconductor device in accordance with example embodiments;

FIG. 36 is a cross-sectional view illustrating a method of manufacturing a semiconductor device in accordance with example embodiments;

FIG. 37 is a perspective view illustrating a method of manufacturing a semiconductor device in accordance with example embodiments;

FIG. 38 is a cross-sectional view illustrating a method of manufacturing a semiconductor device in accordance with example embodiments;

FIG. 39 is a perspective view illustrating a method of manufacturing a semiconductor device in accordance with example embodiments;

FIG. 40 is a perspective view illustrating a method of manufacturing a semiconductor device in accordance with example embodiments;

FIG. 41 is a perspective view illustrating a method of manufacturing a semiconductor device in accordance with example embodiments;

FIG. 42 is a perspective view illustrating a method of manufacturing a semiconductor device in accordance with example embodiments;

FIG. 43 is a cross-sectional view illustrating a method of manufacturing a semiconductor device in accordance with example embodiments;

FIG. 44 is a cross-sectional view illustrating a method of manufacturing a semiconductor device in accordance with example embodiments;

FIG. 45 is a perspective view illustrating a method of manufacturing a semiconductor device in accordance with example embodiments;

FIG. 46 is a perspective view illustrating a method of manufacturing a semiconductor device in accordance with example embodiments;

FIG. 47 is a perspective view illustrating a method of manufacturing a semiconductor device in accordance with example embodiments;

FIG. 48 is a perspective view illustrating a method of manufacturing a semiconductor device in accordance with example embodiments;

FIG. 49 is a perspective view illustrating a method of manufacturing a semiconductor device in accordance with example embodiments;

FIG. 50 is a perspective view illustrating a method of manufacturing a semiconductor device in accordance with example embodiments;

FIG. 51 is a cross-sectional view illustrating a method of manufacturing a semiconductor device in accordance with example embodiments;

FIG. 52 is a cross-sectional view illustrating a method of manufacturing a semiconductor device in accordance with example embodiments;

FIG. 53 is a perspective view illustrating a semiconductor device in accordance with example embodiments; and

FIG. 54 is a perspective view illustrating a semiconductor device in accordance with example embodiments.

### DETAILED DESCRIPTION

The above and other aspects and features of a semiconductor device and a method of manufacturing the same in accordance with example embodiments will become readily understood from detail descriptions that follow, with reference to the accompanying drawings. It will be understood that, although the terms “first,” “second,” and/or “third” may be used herein to describe various elements, components, regions, layers and/or sections, these elements, components, regions, layers and/or sections should not necessarily be limited by these terms. These terms are used to distinguish one element, component, region, layer or section from another region, layer or section. Thus, a first element, component, region, layer or section discussed below could be termed a second or third element, component, region, layer or section without departing from the teachings of inventive concepts.

Hereinafter, in the specification (and not necessarily in the claims), a vertical direction that is substantially perpendicular to an upper surface of a substrate may be referred to as a first direction D1, and two intersecting directions among horizontal directions that are substantially parallel to the upper surface of the substrate may be referred to as second and third directions D2 and D3, respectively. In example embodiments, the second and third directions D2 and D3 are substantially perpendicular to each other. Each of the first to third directions D1, D2 and D3 may include not only a direction shown in the drawings but also a direction inverse thereto.

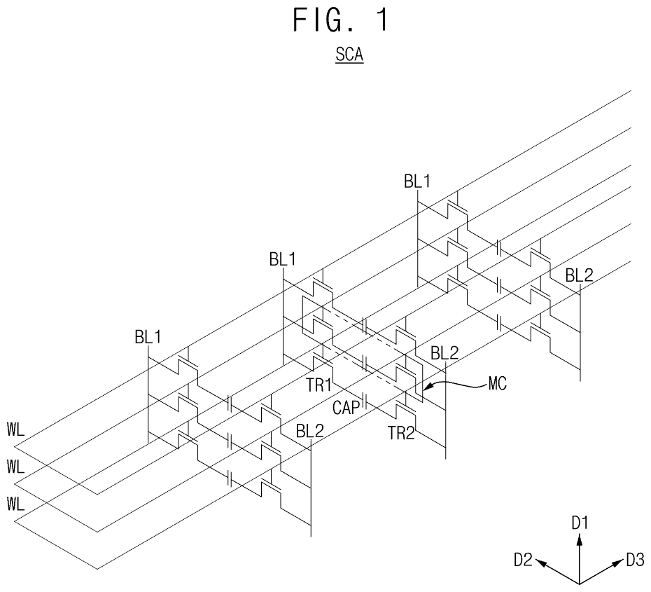

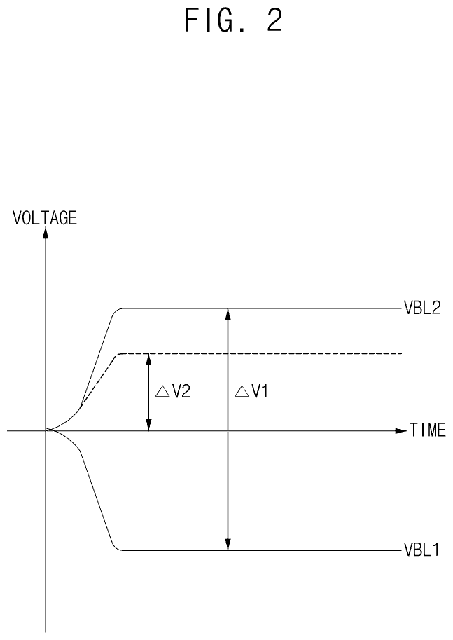

FIG. 1 is an equivalent circuit diagram illustrating a sub-cell array included in a cell array of a semiconductor device, and FIG. 2 is a graph illustrating a voltage change of a bit line included in the semiconductor device.

Referring to FIG. 1, the cell array of the semiconductor device may include a plurality of sub-cell arrays SCA, arranged in the second direction D2, and each of the sub-cell arrays SCA may include a plurality of first bit lines BL1, a plurality of second bit lines BL2, a plurality of word lines WL and a plurality of memory cells MC.

In each of the sub-cell arrays SCA, each of the first and second bit lines BL1 and BL2 may extend primarily in the first direction D1, and a plurality of first bit lines BL1 may be spaced apart from each other in the third direction D3 and a plurality of second bit lines BL2 may be spaced apart from in the third direction D3. Neighboring ones of the first and second bit lines BL1 and BL2 in the second direction D2 may form a bit line pair.

In each of the sub-cell arrays SCA, the memory cell MC may be disposed between the first and second bit lines BL1 and BL2 included in the bit line pair, and a plurality of memory cells MC may be spaced apart from each other in the first direction D1 in each of the bit line pair.

In example embodiments, each of the memory cells MC may include a first transistor TR1, a second transistor TR2 and a capacitor CAP disposed between the first and second transistors TR1 and TR2. The first transistor TR1 may include a first gate electrode and first and second source/drain layers at opposite sides of the first gate electrode, and the second transistor TR2 may include a second gate electrode and first and second source/drain layers at opposite sides of the second gate electrode.

The first source/drain layer included in the first transistor TR1 may be electrically connected to the first bit line BL1, and the second source/drain layer included in the first transistor TR1 may be electrically connected to a first electrode of the capacitor CAP. Additionally, the first source/drain layer included in the second transistor TR2 may be electrically connected to the second bit line BL2, and the second source/drain layer included in the second transistor TR2 may be electrically connected to a second electrode of the capacitor CAP.

In example embodiments, the first gate electrodes included in a plurality of first transistors TR1, respectively, disposed in the third direction D3 at a first level may be electrically connected to a first one of the word lines WL extending in the third direction D3 at the first level, and the second gate electrodes included in a plurality of second transistors TR2, respectively, disposed in the third direction D3 at a second level may be electrically connected to a second one of the word lines WL extending primarily in the third direction D3 at the second level.

As used herein, the phrase “extending primarily in a direction” is understood to mean that the element that is so-extending, is an element occupying two or three dimensions in space and so its primary direction of extension is that one direction that the element extends in to the greatest extent, e.g., the length direction. Thus, to the extent that a word line WL extends primarily in the third direction D3, that word line WL has its longest dimension aligned in the third direction D3.

In example embodiments, when the first one of the word lines WL electrically connected to the first gate electrodes and the second one of the word lines WL electrically connected to the second gate electrodes are disposed at the same level, the first one of the word lines WL and the second one of the word lines WL may be electrically connected to each other, and thus the first and second gate electrodes at the same level may be electrically connected to the same word line WL.

Referring to FIG. 1 together with FIG. 2, when the memory cell MC is turned on, a source voltage may be supplied to the second bit line BL2 and a ground voltage may be supplied to the first bit line BL1, so that charge may be stored in the capacitor CAP. When the memory cell MC is turned off, by the charge stored in the capacitor CAP, the voltage of the second bit line BL2 may be changed into a second saturation voltage VLB2 having a positive value, and the voltage of the first bit line BL1 may be changed into a first saturation voltage VLB1 having a negative value. A bit line sense amplifier may sense a first saturation voltage difference ΔV1, which is a difference between the first and second bit line saturation voltages VBL1 and VBL2, and may amplify the first saturation voltage difference ΔV1.

The memory cell MC of the semiconductor device may have a 2T-1C structure including two transistors, for example, the first and second transistors TR1 and TR2 and one capacitor CAP disposed therebetween, and thus the first saturation voltage difference ΔV1 between the first and second saturation voltages VBL1 and VBL2 of the first and second bit lines BL1 and BL2, respectively, may be greater than a second saturation voltage difference ΔV2 of first and second bit lines BL1 and BL2 in a semiconductor device including a memory cell having a 1T-1C structure. Accordingly, the bit line sense amplifier of the semiconductor device may have an increased sensing margin.

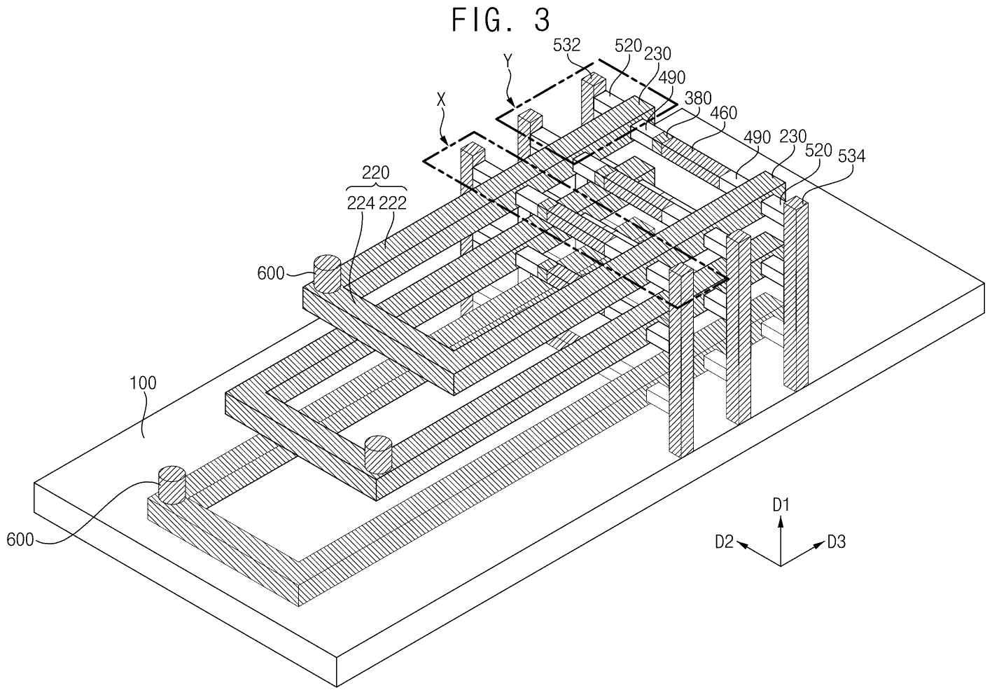

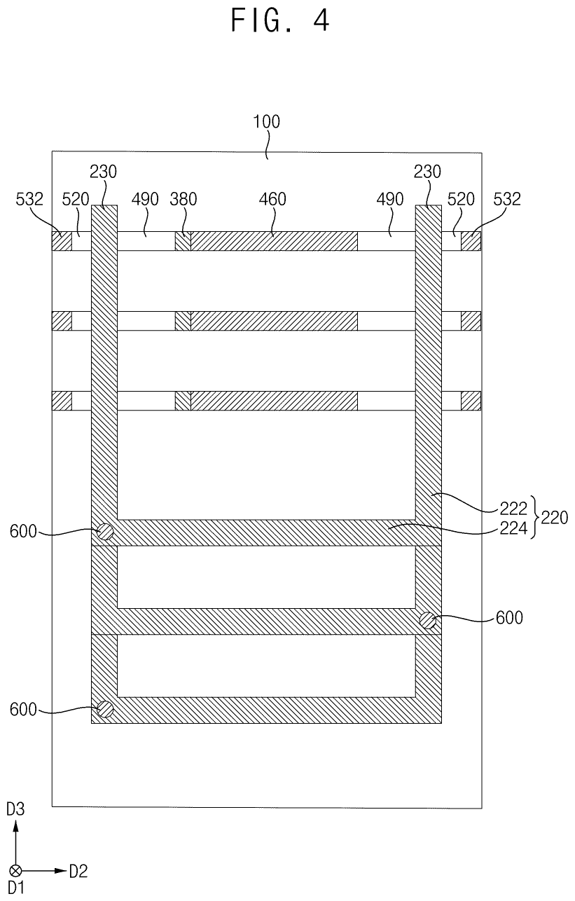

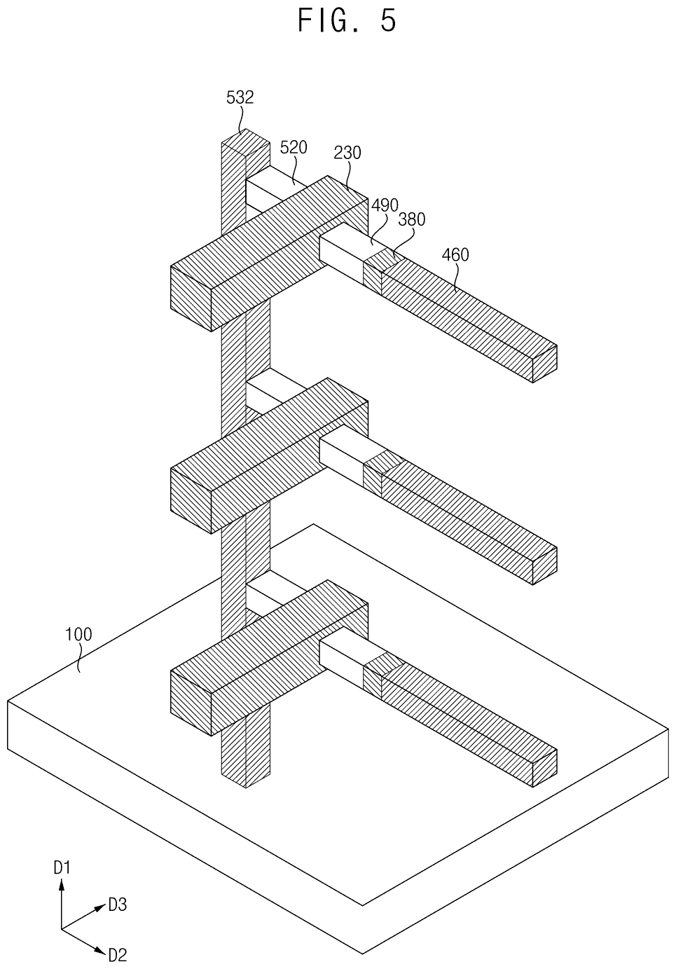

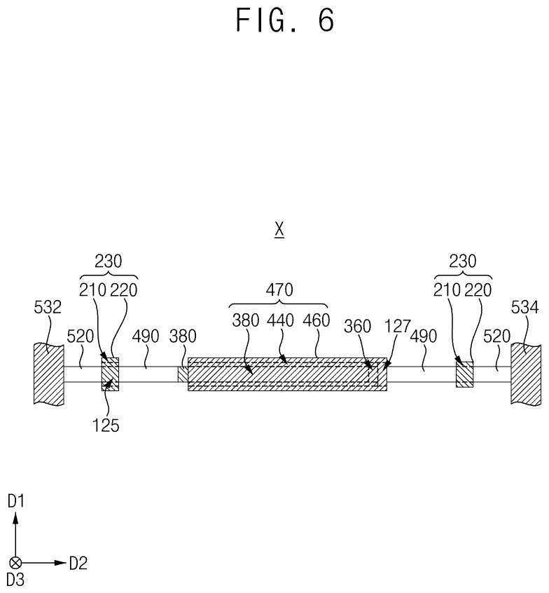

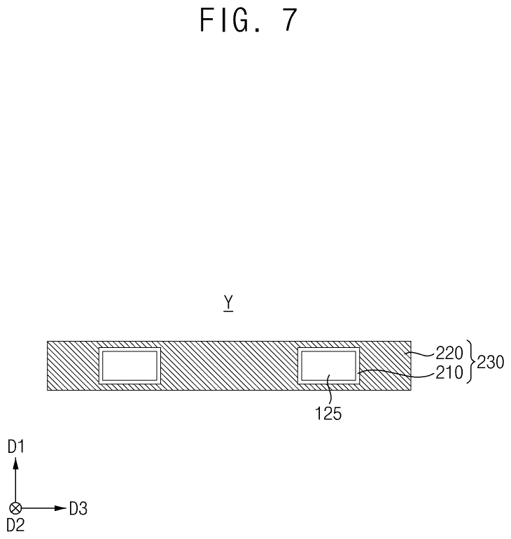

FIGS. 3 to 7 are perspective views, a plan view and cross-sectional views illustrating a semiconductor device in accordance with example embodiments. Particularly, FIGS. 3 and 5 are the perspective views, FIG. 4 is the plan view, FIG. 6 is a cross-sectional view of region X of FIG. 3 taken along the vertical direction, and FIG. 7 is a cross-sectional view of region Y of FIG. 3 taken along the vertical direction. FIG. 5 is a perspective view of a portion of the semiconductor device, which is a perspective view according to different angle from that of FIG. 3.

FIGS. 3 to 7 are drawings illustrating a portion of the sub-cell array SCA of the semiconductor device shown in FIG. 1.

Referring to FIGS. 3 to 7, the semiconductor device may include a gate structure 230, a channel 125, first and second source/drain layers 520 and 490, a capacitor 470, first and second bit lines 532 and 534, a contact plug 600, a connection pattern 127 and an insulation pattern 360 on a substrate 100.

The semiconductor device may further include an insulating interlayer that is disposed on the substrate 100 and covers the above structures.

The substrate 100 may include a semiconductor material, e.g., silicon, germanium, silicon-germanium, etc., or a III-V group compound semiconductor, such as GaP, GaAs, GaSb, etc. In an example embodiment, the substrate 100 may be a silicon-on-insulator (SOI) substrate or a germanium-on-insulator (GOI) substrate.

The substrate 100 may include first and second regions I and II. The first region I may be a cell region in which memory cells are formed, and the second region II may be an extension region in which contact plugs 600 for transferring electrical signals to the memory cells are formed. In an example embodiment, the second region II may be disposed at a side in the third direction D3 of the first region I. However, the inventive concept is not necessarily limited thereto, and for example, the second region II may be disposed at each of opposite sides in the third direction D3 of the first region I, or may at least partially surround the first region I.

The substrate 100 may further include a third region that is a peripheral circuit region in which peripheral circuit patterns are formed. The third region may at least partially surround the first and second regions I and II, or may be disposed under or over the substrate 100, so that the semiconductor device may have a cell over periphery (COP) structure or a periphery over cell (POC) structure. As used herein, the phrase “at least partially surround” is understood to mean that the surrounding element contacts the surrounded element on at least one side or portion thereof, may contact the surrounded element on two sides, whether those sides are opposite sides or proximate sides, may contact the surrounded element on more than two sides, and may even completely surround the surrounded element.

Each of the first and second bit lines 532 and 534 may extend primarily in the first direction D1 on the first region I of the substrate 100, and a plurality of first bit lines 532 may be spaced apart from each other in the third direction D3 and a plurality of second bit lines 534 may be spaced apart from each other in the third direction D3. The first and second bit lines 532 and 534 neighboring in the second direction D2 may form a bit line pair. In example embodiments, a plurality of bit line pairs may be spaced apart from each other in the third direction D3. Each of the first and second bit lines 532 and 534 may have a shape of, e.g., a polygon, a polygon with rounded corners, a circle, an ellipse, etc.

A memory cell may extend primarily in the second direction D2 between the first and second bit lines 532 and 534. In example embodiments, the memory cell may include the capacitor 470, a first transistor between the capacitor 470 and the first bit line 523 and a second transistor between the capacitor 470 and the second bit line 534. Each of the first and second transistors may include the second source/drain layer 490, the channel 125 and the first source/drain layer 520 sequentially disposed between the capacitor 470 and each of the first and second bit lines 532 and 534, and the gate structure 230 surrounding the channel 125.

In example embodiments, a plurality of memory cells may be spaced apart from each other in the first direction D1 between the bit line pairs. As a plurality of bit line pairs are spaced apart from each other in the third direction D3, and thus a plurality of memory cells may be spaced apart from each other in the third direction D3. FIGS. 3 to 7 show three memory cells spaced apart from each other in the third direction D3 at each of three levels spaced apart from each other in the first direction D1 on the substrate 100, however, the inventive concept is not necessarily limited thereto.

In example embodiments, the capacitor 470 may include a first capacitor electrode 380 having a pillar shape extending primarily in the second direction D2, a dielectric pattern 440 having a shape of a hollow cylinder that may surround a surface, for example, lower and upper surfaces and opposite sidewalls in the third direction D3 of the first capacitor electrode 380, and a second capacitor electrode 460 having a hollow cylinder that may surround a surface, for example, lower and upper surfaces and opposite outer sidewalls in the third direction D3 of the dielectric pattern 440. However, the inventive concept is not necessarily limited thereto, and for example, the first capacitor electrode 380 may have a shape of a hollow cylinder instead of the pillar shape, and the second capacitor electrode 460 may have a shape of a hollow cylinder instead of the pillar shape.

In an example embodiment, the dielectric pattern 440 might not cover a surface, for example, lower and upper surfaces and opposite sidewalls in the third direction D3 of a portion of the first capacitor electrode 380 adjacent to the second source/drain layer 490 included in the first transistor.

In an example embodiment, a cross-section in the third direction D3 of the first capacitor electrode 380 may have a shape of a rectangle. However, the inventive concept is not necessarily limited thereto, and the cross-section in the third direction D3 of the first capacitor electrode 380 may have a shape of, e.g., a polygon, a polygon with rounded corners, a circle, an ellipse, etc.

In example embodiments, a first sidewall in the second direction D2 of the first capacitor electrode 380 may contact a sidewall in the second direction D2 of the second source/drain layer 490 included in the first transistor, and may be electrically connected thereto. A second sidewall in the second direction D2 of the first capacitor electrode 380 might not contact a sidewall in the second direction D2 of the second source/drain layer 490 included in the second transistor.

In example embodiments, the insulation pattern 360 and the connection pattern 127 may be sequentially disposed between and contact the second sidewall of the first capacitor electrode 380 and the sidewall in the second direction D2 of the second source/drain layer 490 included in the second transistor. Each of the insulation pattern 360 and the connection pattern 127 may have a shape of a pillar extending primarily in the second direction D2, and an extension length in the second direction D2 of each of the insulation pattern 360 and the connection pattern 127 may be smaller than that of the first capacitor electrode 380.

A cross-section in the third direction D3 of each of the insulation pattern 360 and the connection pattern 127 may be substantially the same as that of the first capacitor electrode 380. In an example embodiment, a thickness and a width in the first and third directions D1 and D3, respectively, of the insulation pattern 360 may be substantially the same as a thickness and a width in the first and third directions D1 and D3, respectively, of the first capacitor electrode 380, and a thickness and a width in the first and third directions D1 and D3, respectively, of the connection pattern 127 may be substantially the same as a thickness and a width in the first and third directions D1 and D3, respectively, of a structure including the first capacitor electrode 380 and the dielectric pattern 440, however, the inventive concept is not necessarily limited thereto.

As used herein, the phrase, “substantially the same” may mean that the two elements subject to the comparison are equal in the recited aspect, or are nearly equal such that they appear to be equal but may vary to an imperceptible and/or insignificant degree such as by 10%, 5%, 2%, 1%, or less than 1%.

The insulation pattern 360 may include an insulating material. The connection pattern 127 may include a semiconductor material doped with n-type or p-type impurities, e.g., silicon doped with n-type or p-type impurities or silicon-germanium doped with n-type or p-type impurities. Alternatively, the connection pattern 127 may include an oxide semiconductor material doped with n-type or p-type impurities, e.g., IGZO doped with n-type or p-type impurities.

As the insulation pattern 360 is disposed between the second sidewall in the second direction D2 of the first capacitor electrode 380 and the sidewall in the second direction D2 of the second source/drain layer 490 included in the second transistor, the first capacitor electrode 380 might not be electrically connected to the second source/drain layer 490 included in the second transistor.

The dielectric pattern 440 may cover not only the lower and upper surfaces and opposite sidewalls in the third direction D3 of the first capacitor electrode 380 but also a surface, for example, lower and upper surfaces and opposite sidewalls in the third direction D3 of the insulation pattern 360.

The second capacitor electrode 460 may cover not only the lower and upper surfaces and opposite outer sidewalls in the third direction D3 of the dielectric pattern 440 but also a surface, for example, lower and upper surfaces and opposite sidewalls in the third direction D3 of the connection pattern 127. Thus, the second capacitor electrode 460 may contact the connection pattern 127 so as to be electrically connected to the second source/drain layer 490 included in the second transistor, which may contact the connection pattern 127. The second capacitor electrode 460 may be spaced apart from the second source/drain layer 490 included in the first transistor so as not to be electrically connected thereto.

Each of the first and second capacitor electrodes 380 and 460 may include an electrically conductive material, e.g., a metal, a metal nitride, a metal silicide, doped silicon-germanium, etc. The dielectric pattern 440 may include a metal oxide having a high dielectric constant, e.g., hafnium oxide, zirconium oxide, etc., or a ferroelectric material. As used herein, the phrase, “high dielectric constant” may be understood to be a dielectric constant greater than that of silicon oxide.

The channel 125 may include a semiconductor material, e.g., silicon, germanium, silicon-germanium, etc. Alternatively, the channel 125 may include an oxide semiconductor material such as zinc tin oxide (ZTO), indium zinc oxide (IZO), zinc oxide (ZnOₓ), indium gallium zine oxide (IGZO), indium gallium silicon oxide (IGSO), Indium oxide (InOₓ, In₂O₃), tin oxide (SnO₂), titanium oxide (TiOₓ), zinc oxide nitride (ZnₓO_{y}N_{z}), magnesium zinc oxide (MgₓZn_{y}O_{z}), indium zinc oxide (InₓZn_{y}Oₐ), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ, zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ), and/or indium gallium silicon oxide (InGaSiO).

Each of the first and second source/drain layers 520 and 490 may include substantially the same material as the channel 125, however, n-type or p-type impurities may be doped thereinto. The first and second source/drain layers 520 and 490 may include the same conductivity type of impurities.

In example embodiments, the gate structure 230 may include a gate insulation pattern 210 covering a surface, for example, lower and upper surfaces and opposite sidewalls in the third direction D3 of the channel 125, and a gate electrode 220 covering a surface, for example, lower and upper surfaces and opposite outer sidewalls in the third direction D3 of the gate insulation pattern 210. Thus, the channel 125 may extend through the gate structure 230 in the second direction D2, and the gate structure 230 may have a gate all around (GAA) structure surrounding the channel 125.

Alternatively, the gate structure 230 may have a single gate structure or a double gate structure instead of the GAA structure. For example, the gate structure 230 may be disposed on or beneath the channel 125, or two gate structures 230 may be disposed on and beneath, respectively, the channel 125, instead of surrounding the channel 125.

As a result, if only the gate structure 230 is electrically connected to the channel 125, the gate structure 230 may have various other types of structures.

In example embodiments, the gate electrodes 220, which surround the channels 125 disposed in the third direction D3 at the same level and the gate insulation patterns 210 covering the channels 125 and are disposed adjacent to each other in the third direction D3, may be connected to each other, and thus may form a word line extending primarily in the third direction D3 on the first and second regions I and II of the substrate 100. Additionally, the word lines, each of which may extend primarily in the third direction D3, spaced apart from each other in the second direction D2 at the same level may extend on the second region II of the substrate 100 to be connected to each other. The connected word lines may be integrally formed. As used herein, the phrase “integrally formed” may mean that the two elements are formed together as a single, continuous, and uninterrupted structure.

Hereinafter, in a word line that may be integrally formed by two connected word lines at the same level, portions extending primarily in the third direction D3 may be referred to as first extension portions 222, respectively, and a portion extending primarily in the second direction D2 to contact the first extension portions 222 may be referred to as a second extension portion 224. A portion of each of the first extension portions of the word line that may at least partially surround the channel 125 included in a single memory cell may be defined as the gate electrode 220.

As a result, the two gate electrodes 220 at opposite sides, respectively, in the second direction D2 of the capacitor 470 at the same level may be electrically connected to the same word line, and the gate electrodes 220 disposed in the third direction D3 at the same level may also be electrically connected to the same word line.

In example embodiments, the second extension portions 224 of the word line may be disposed in the third direction D3 in a stepwise manner on the second region II of the substrate 100.

In an example embodiment, lengths in the third direction D3 of the first extension portions 222 of the word line connected to the second extension portions 224 of the word line may increase from an uppermost level to a lowermost level.

Alternatively, the lengths in the third direction D3 of the first extension portions 222 of the word line connected to the second extension portions 224 of the word line may decrease from the uppermost level to the lowermost level.

Alternatively, the lengths in the third direction D3 of the first extension portions 222 of the word line connected to the second extension portions 224 of the word line may increase and then decrease from the uppermost level to the lowermost level, or decrease and then increase from the uppermost level to the lowermost level.

The gate electrode 220 may include an electrically conductive material, e.g., a metal, a metal nitride, a metal silicide, etc., and the gate insulation pattern 210 may include an oxide, e.g., silicon oxide, a metal oxide, etc.

The contact plug 600 may be disposed on and may contact the second extension portion 224 of the word line on the second region II of the substrate 100. In example embodiments, one contact plug 600 or a plurality of contact plugs 600 may be disposed on the second extension portion 224 of the word line in a variety of layouts.

FIGS. 3 to 7 show that each of the contact plugs 600 is disposed on an interface between the first and second extension portions 222 and 224, and the contact plugs 600 are arranged in a zigzag pattern in a plan view, however, the inventive concept is not necessarily limited thereto. For example, each of the contact plugs 600 may also be disposed on, e.g., a central portion of the second extension portion 224, and the contact plugs 600 may be arranged in a zigzag pattern in a plan view. The contact plug 600 may include an electrically conductive material, e.g., a metal, a metal nitride, a metal silicide, etc.

In the semiconductor device, the gate electrode 220, the channel 125 and the first and second source/drain layers 520 and 490 may form each of first and second transistors. The first source/drain layer 520 of the first transistor may be electrically connected to the first bit line 532, and the second source/drain layer 490 of the first transistor may be electrically connected to the first capacitor electrode 380 included in the capacitor 470. Additionally, the first source/drain layer 520 of the second transistor may be electrically connected to the second bit line 534, and the second source/drain layer 490 of the second transistor may be electrically connected to the second capacitor electrode 460 included in the capacitor 470 through the connection pattern 127. The gate electrodes 220 included in the first and second transistors, respectively, may be connected to the same word line.

Thus, each of the memory cells of the semiconductor device may have a 2T-1C structure including the first and second transistors and the capacitor 470 therebetween, and the bit line sense amplifier may have high sensing margin.

Additionally, when the semiconductor device has a COP structure or a POC structure, the bit line sense amplifier may be disposed under or over the first and second bit lines 532 and 534, which may be disposed at the same level, and thus may be spaced apart from the first and second bit lines 532 and 534 by the same distance. For example, if the first and second bit lines 532 and 534 extends in the horizontal direction at different levels, respectively, distances from a bit line sense amplifier, which may be disposed under or over the first and second bit lines 532 and 534, to the first and second bit lines 532 and 534 may be different from each other, and thus signal delay may occur.

However, in example embodiments, the first and second bit lines 532 and 534 may extend primarily in the same level by the same length, so that the distance from the bit line sense amplifier to the first and second bit lines 532 and 534 may be the same so as not to cause the signal delay.

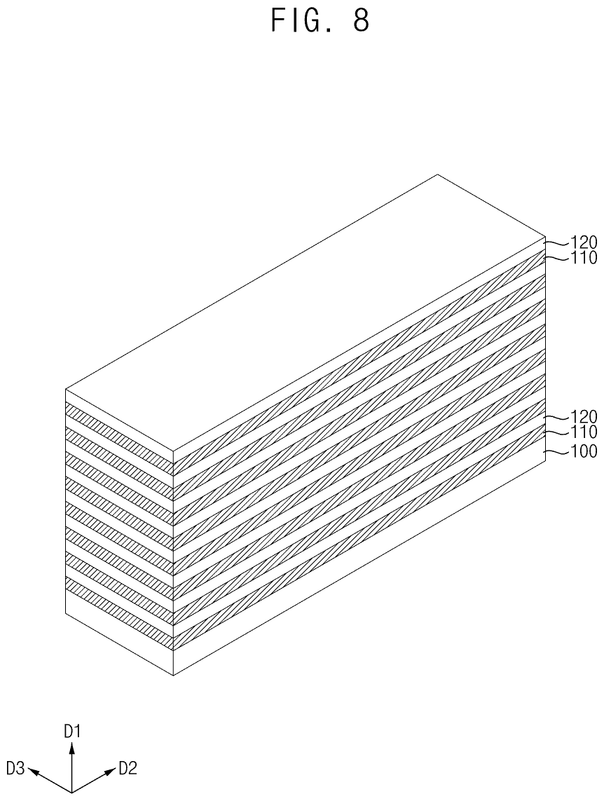

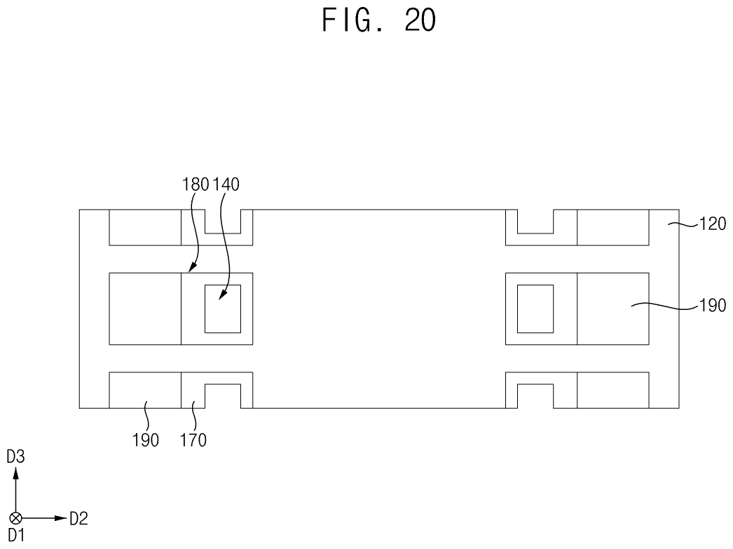

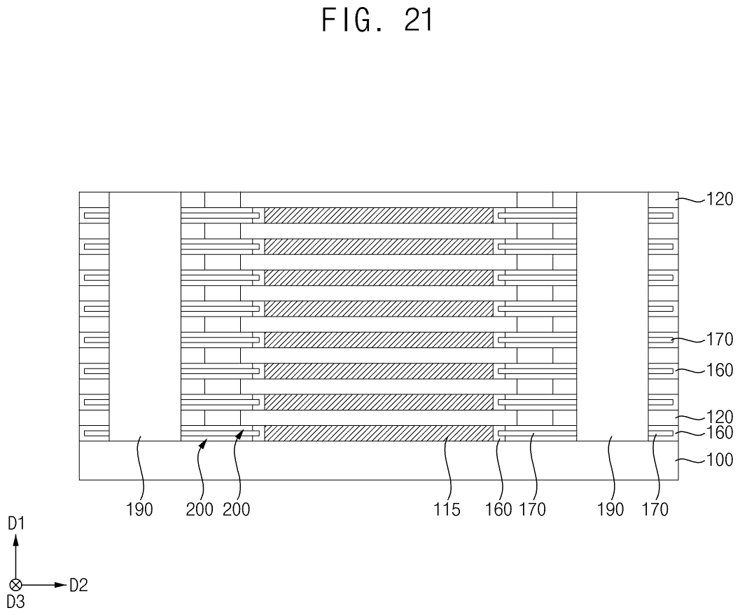

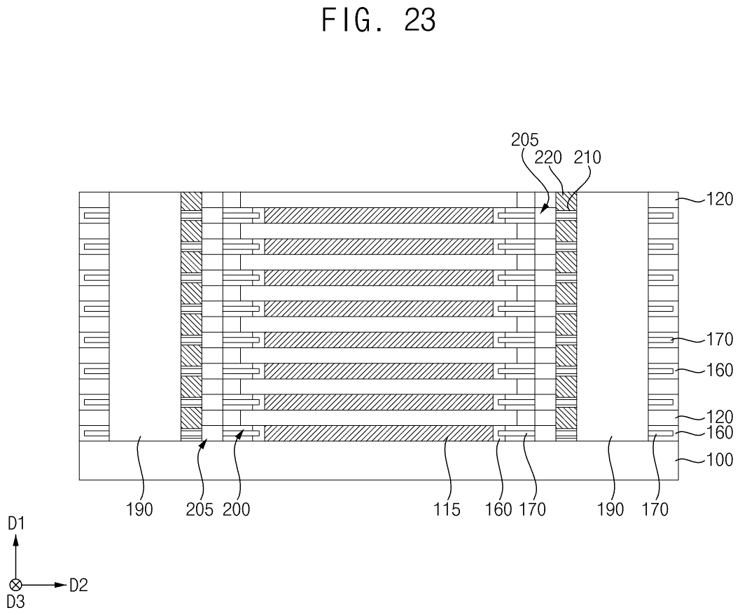

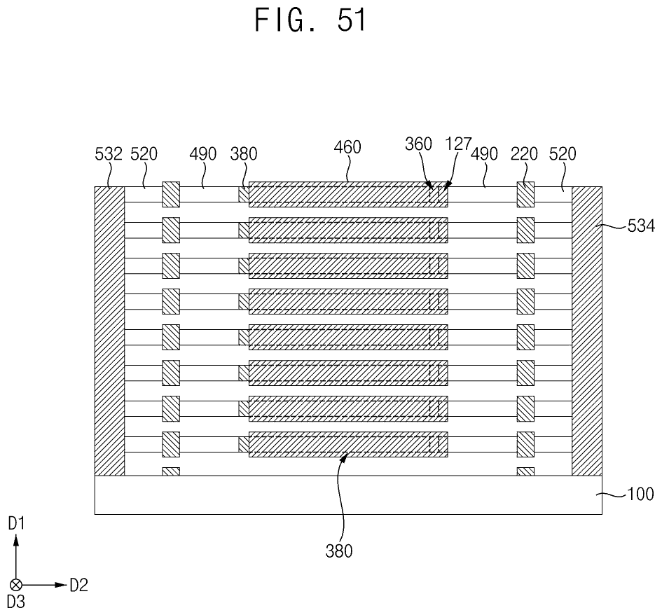

FIGS. 8 to 52 are perspective views, plan views, front views and cross-sectional views illustrating a method of manufacturing a semiconductor device in accordance with example embodiments.

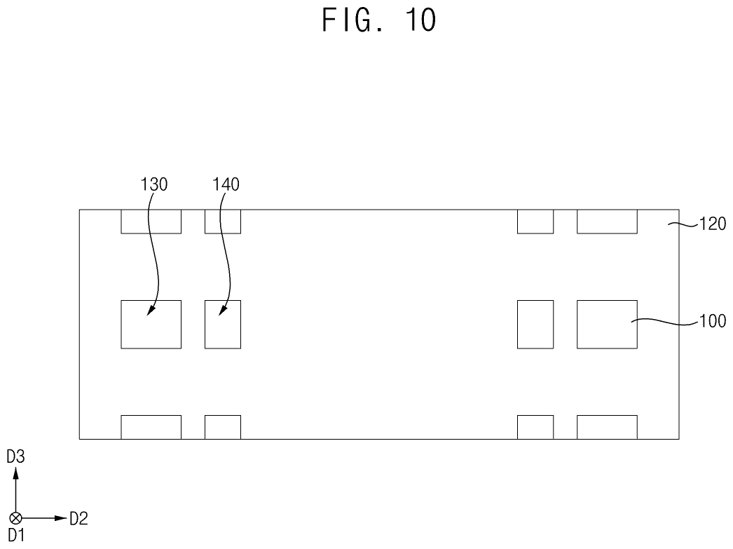

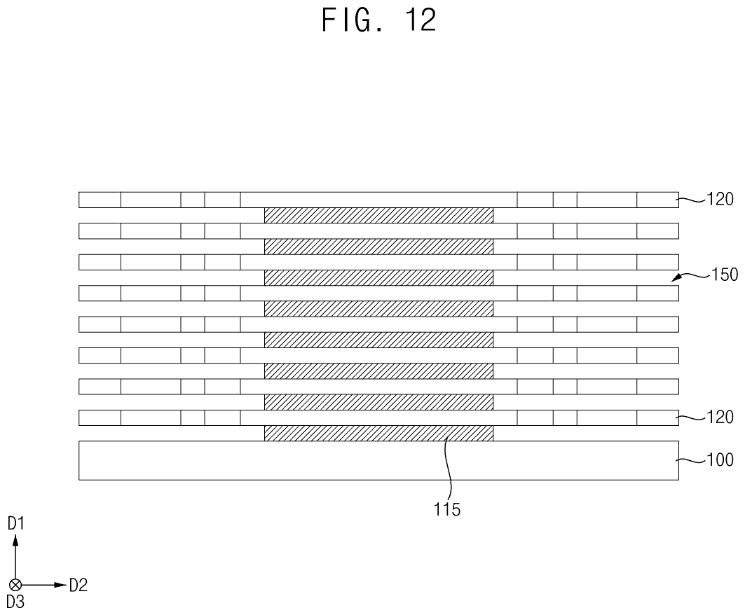

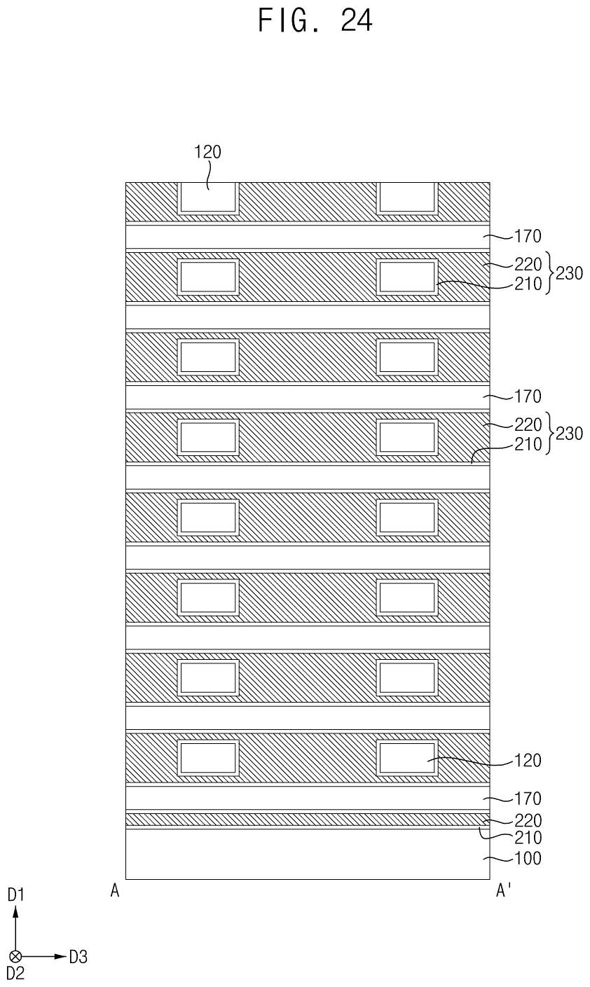

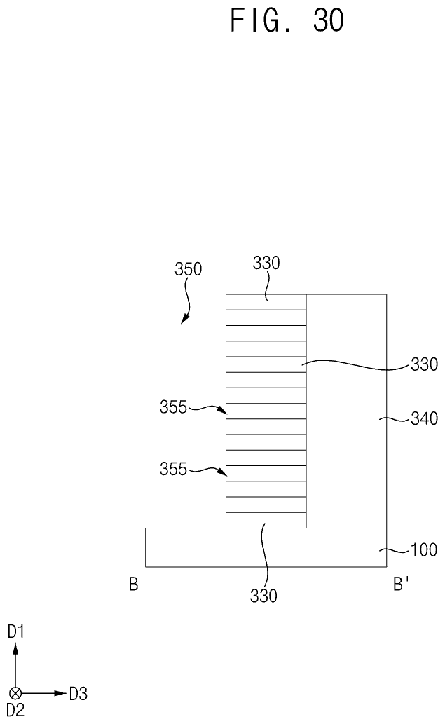

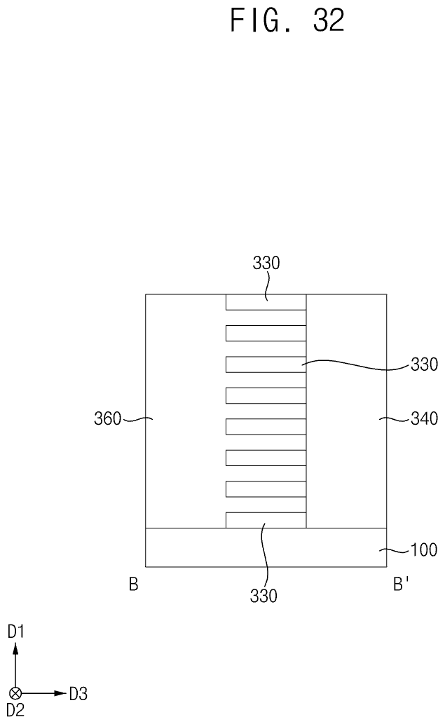

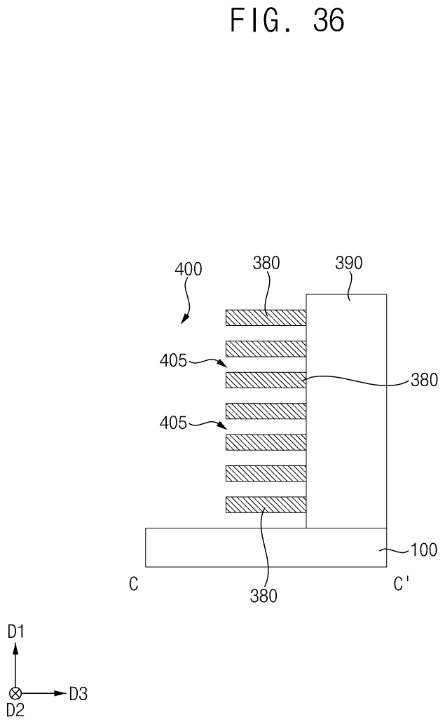

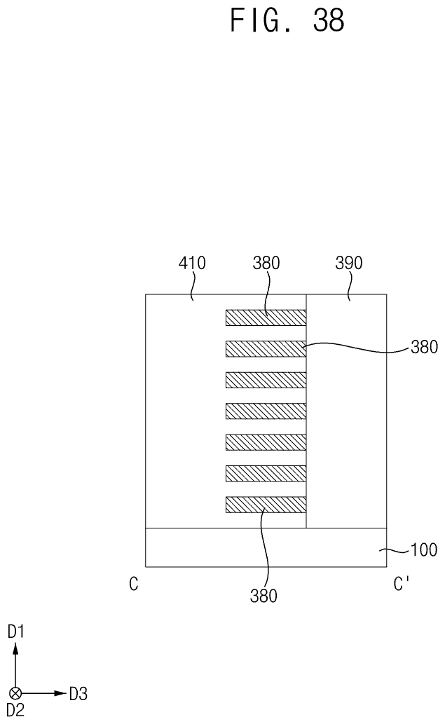

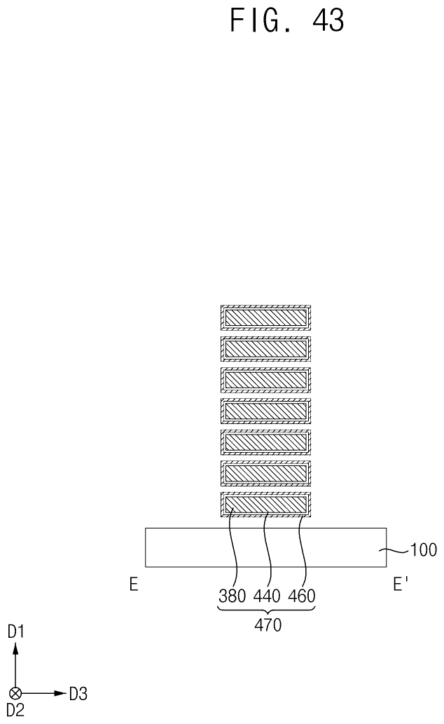

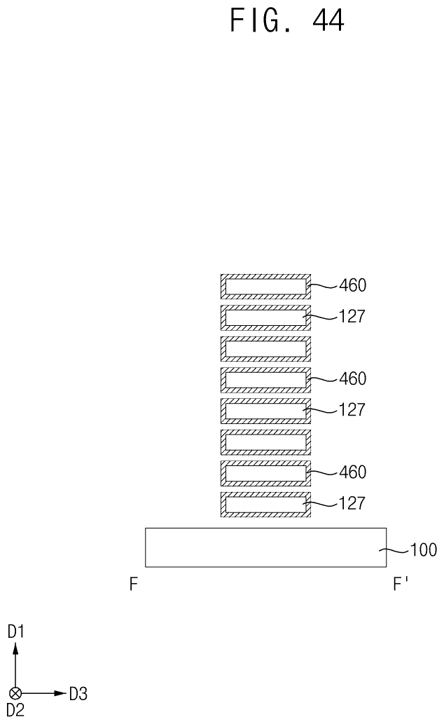

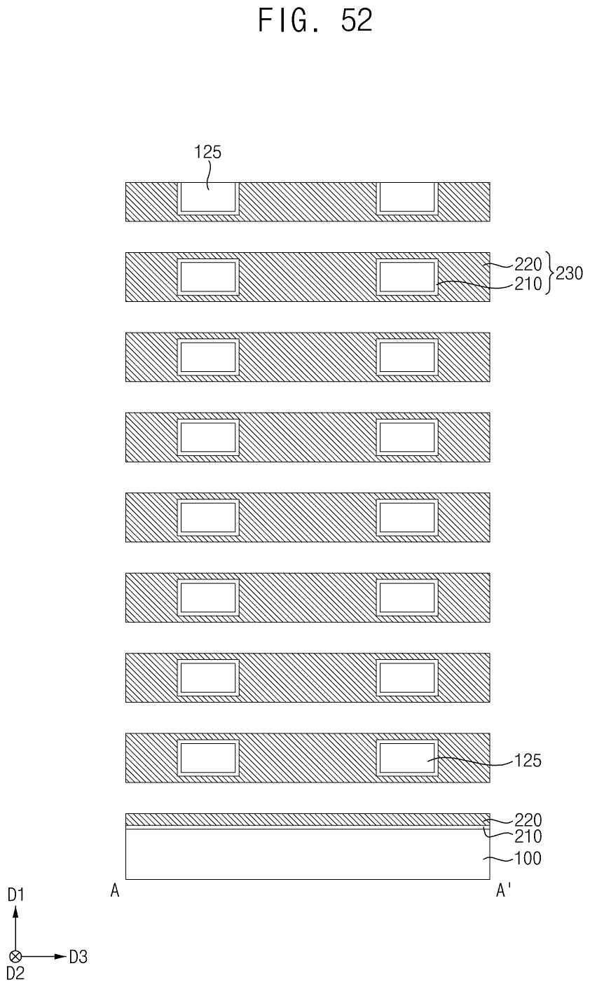

Particularly, FIGS. 8, 9, 11, 13, 15, 17, 19, 22, 25-29, 31, 33-35, 37, 39-42 and 45-50 are the perspective views, FIGS. 10, 16, 18 and 20 are the plan views of corresponding perspective views, respectively, FIGS. 12, 14, 21, 23 and 51 are the front views of corresponding perspective views, respectively, FIGS. 24 and 52 are cross-sectional views taken along lines A-A′ of corresponding perspective views, respectively, FIGS. 30 and 32 are cross-sectional views taken along lines B-B′ of corresponding perspective views, respectively, FIGS. 36 and 38 are cross-sectional views taken along lines C-C′ of corresponding perspective views, respectively, FIG. 43 is a cross-sectional view taken along line E-E′ of a corresponding perspective view, and FIG. 44 is a cross-sectional view taken along line F-F′ of a corresponding perspective view.

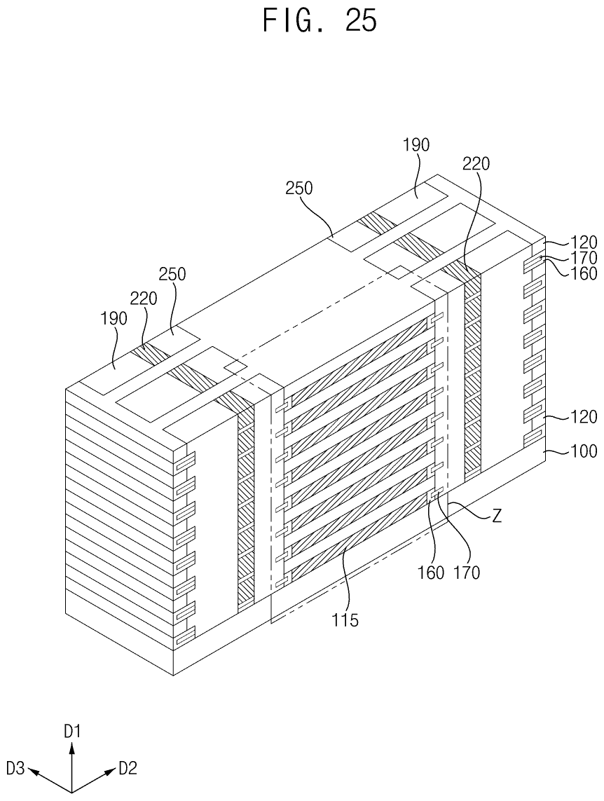

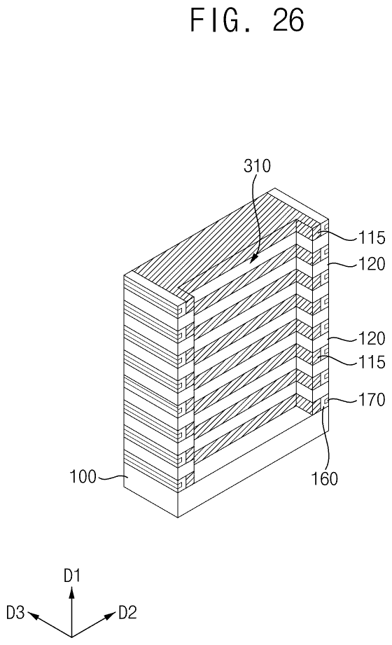

FIGS. 8 to 52 are drawings illustrating a first region of a substrate, and particularly, FIGS. 26 to 46 are drawings illustrating region Z of FIG. 25.

Referring to FIG. 8, a first sacrificial layer 110 and a semiconductor layer 120 may be alternately and repeatedly stacked in the first direction D1 on a substrate 100 including first and second regions I and II (refer to FIGS. 3 and 4) to form a mold layer.

In an example embodiment, the semiconductor layer 120 may include, e.g., silicon, and the first sacrificial layer 110 may include a material having an etching selectivity with respect to the semiconductor layer 120, e.g., silicon-germanium. Alternatively, the semiconductor layer 120 may include silicon-germanium, and the first sacrificial layer 110 may include silicon. Alternatively, the semiconductor layer 120 may include an oxide semiconductor material such as IGZO.

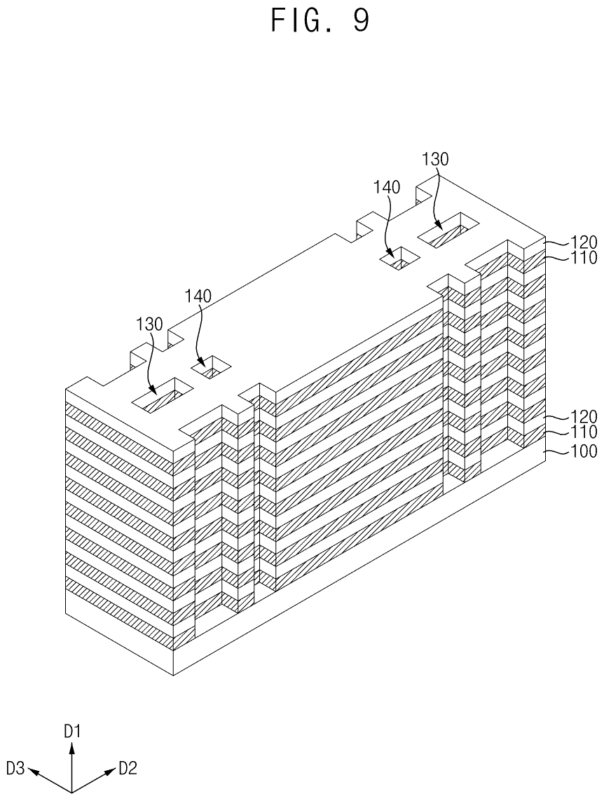

Referring to FIGS. 9 and 10, for example, a dry etching process may be performed on the mold layer to form first and second holes 130 and 140 through the mold layer, which may expose an upper surface of the substrate 100.

Each of the first and second holes 130 and 140 may extend primarily in the first direction D1, and a plurality of first holes 130 may be spaced apart from each other in the second and third directions D2 and D3 and a plurality of second holes 140 may be spaced apart from each other in the second and third directions D2 and D3. In example embodiments, the second and first holes 140 and 130 may be arranged in the second direction D2 in this order from a central portion (hereinafter, referred to as a first portion) in the second direction D2 of the mold layer, and neighboring ones of the first and second holes 130 and 140 in the second direction D2 may form a hole pair.

The mold layer may include a plurality of areas, each of which may include the first portion and opposite edge portions (hereinafter, referred to as second portions, respectively) at opposite sides, respectively, of the first portion in the second direction D2 where the hole pairs are formed. FIGS. 8 to 52 show a first one of the plurality of areas and portions of second ones, respectively, of the plurality of areas at opposite sides, respectively, of the first one in the third direction D3.

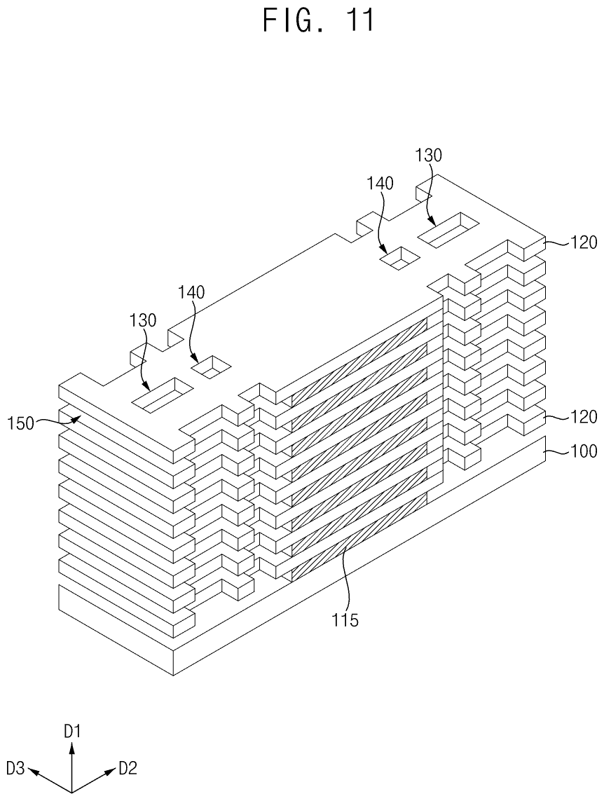

Referring to FIGS. 11 and 12, a portion of the first sacrificial layer 110 adjacent to the first and second holes 130 and 140 may be removed by an etching process to form a first sacrificial pattern 115.

In example embodiments, the etching process may include a wet etching process, and by the etching process, the first sacrificial pattern 115 may remain only in the first portion of the mold layer. Additionally, a first gap 150 may be formed between neighboring ones of the semiconductor layers 120 in the first direction D1 in each of the second portions of the mold layer and a portion of the first portion of the mold layer adjacent to each of the second portions of the mold layer.

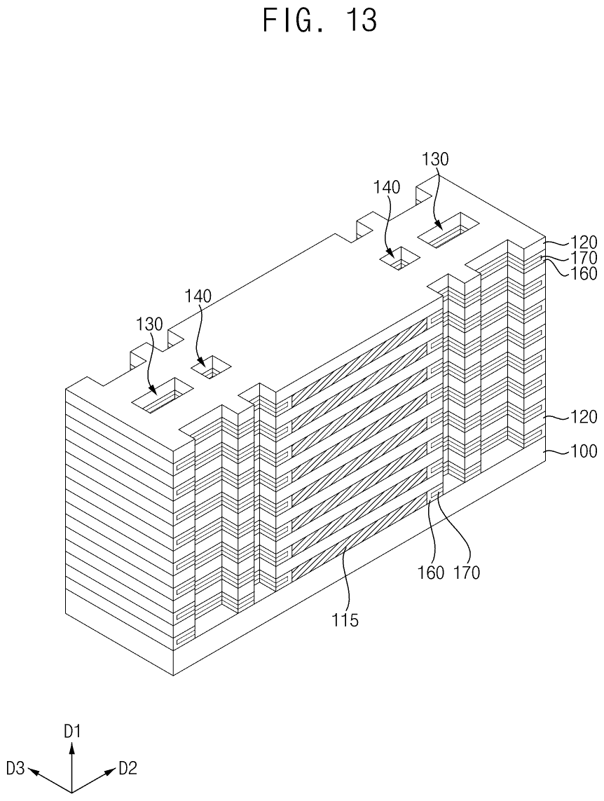

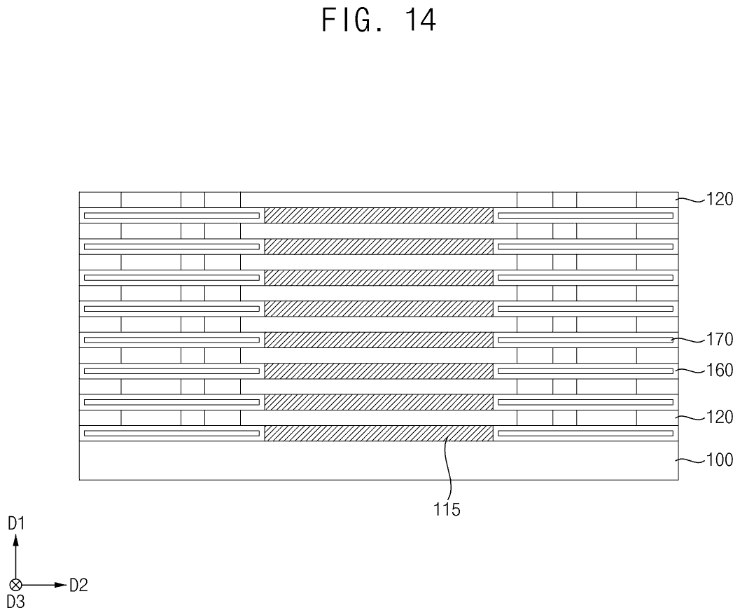

Referring to FIGS. 13 and 14, first and second sacrificial insulation patterns 160 and 170 may be formed in the first gap 150.

In example embodiments, a deposition process, e.g., a chemical vapor deposition (CVD) process, an atomic layer deposition (ALD) process, etc., may be performed to form a first sacrificial insulation layer on inner walls of the first and second holes 130 and 140 and an inner wall of the first gap 150, a second sacrificial insulation layer may be formed on the first sacrificial insulation layer to fill the first gap 150 and a portion or an entire portion of each of the first and second holes 130 and 140, a planarization process may be performed on the first and second sacrificial insulation layers until an upper surface of the mold layer is exposed, and portions of the first and second sacrificial insulation layers in each of the first and second holes 130 and 140 may be removed by, e.g., a dry etching process to form the first and second sacrificial insulation patterns 160 and 170 in the first gap 150.

The planarization process may include a chemical mechanical polishing (CMP) process and/or an etch back process. The first sacrificial insulation pattern 160 may include an insulating nitride, e.g., silicon nitride, and the second sacrificial insulation pattern 170 may include an oxide, e.g., silicon oxide.

As the first and second sacrificial insulation patterns 160 and 170 are formed in the first gap 150, the first sacrificial insulation pattern 160, the second sacrificial insulation pattern 170, the first sacrificial insulation pattern 160 and the semiconductor layer 120 may be alternately and repeatedly stacked in the first direction D1 on each of the second portions of the mold layer and a portion of the first portion of the mold layer adjacent thereto in the second direction D2.

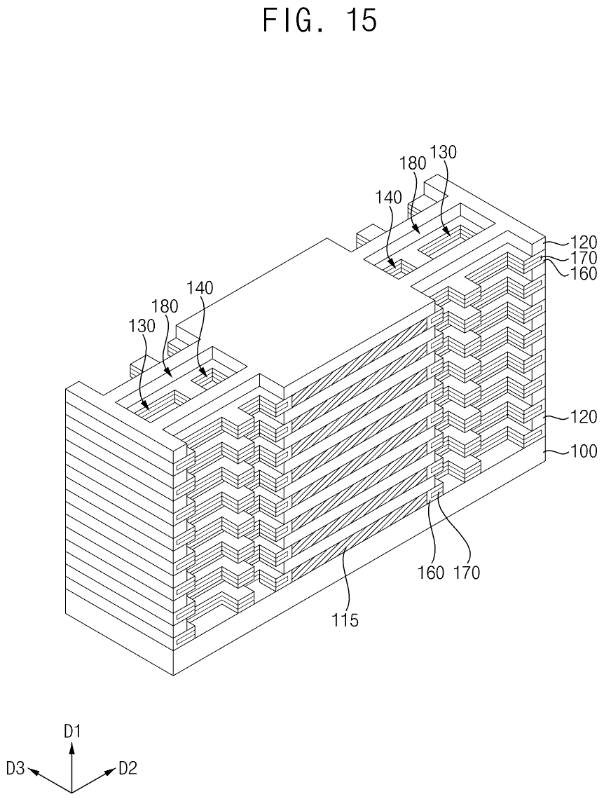

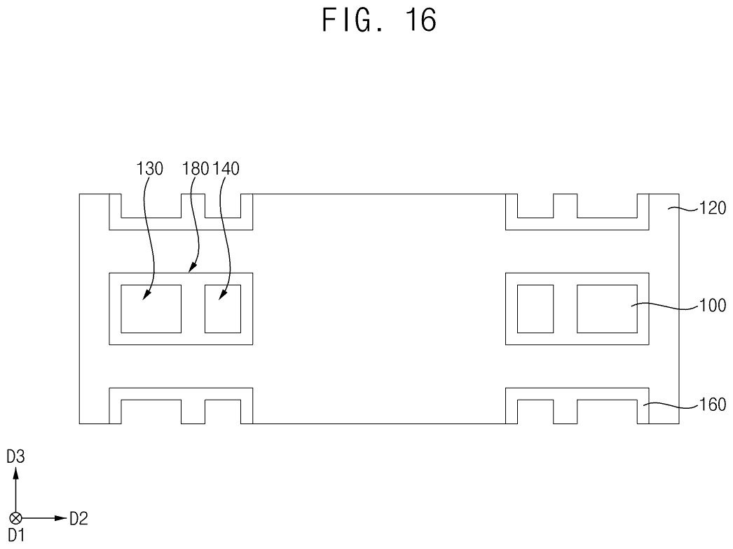

Referring to FIGS. 15 and 16, a portion of the semiconductor layer 120 adjacent to the first and second holes 130 and 140 may be removed by, e.g., a wet etching process, and thus first and second holes 130 and 140 may be enlarged in the horizontal direction at a level where each of the semiconductor layers 120 is formed.

In example embodiments, the first and second holes 130 and 140 included in each hole pair at the level where each of the semiconductor layers 120 is formed may be enlarged to be merged with each other to form a third hole 180 connected to the first and second holes 130 and 140 at a level where the first and second sacrificial insulation patterns 160 and 170 are formed. Hereinafter, a portion of each of the first and second holes 130 and 140 at which each of the semiconductor layers 120 is formed may be referred to as the third hole 180. Lower and upper surfaces of a portion of the first sacrificial insulation pattern 160 in the first gap 150, particularly, a portion of the first sacrificial insulation pattern 160 adjacent to the each of the first and second holes 130 and 140 may be exposed by the third hole 180.

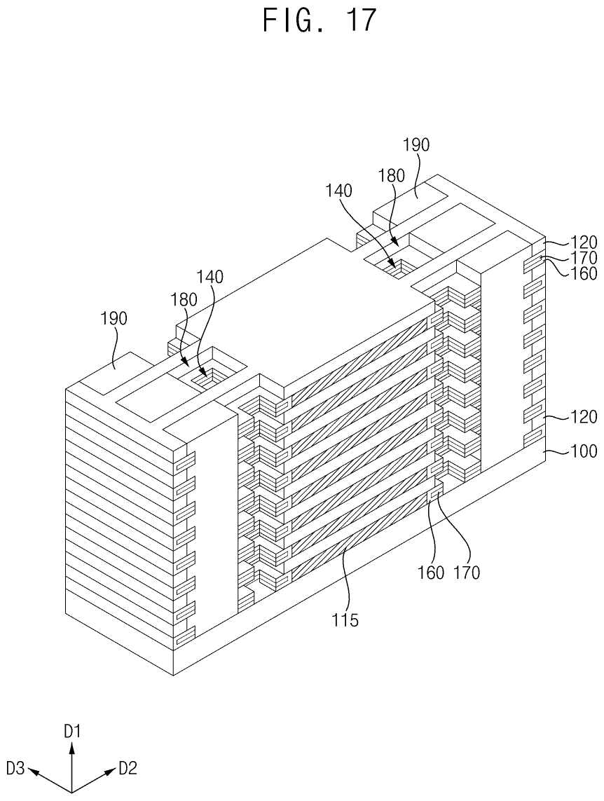

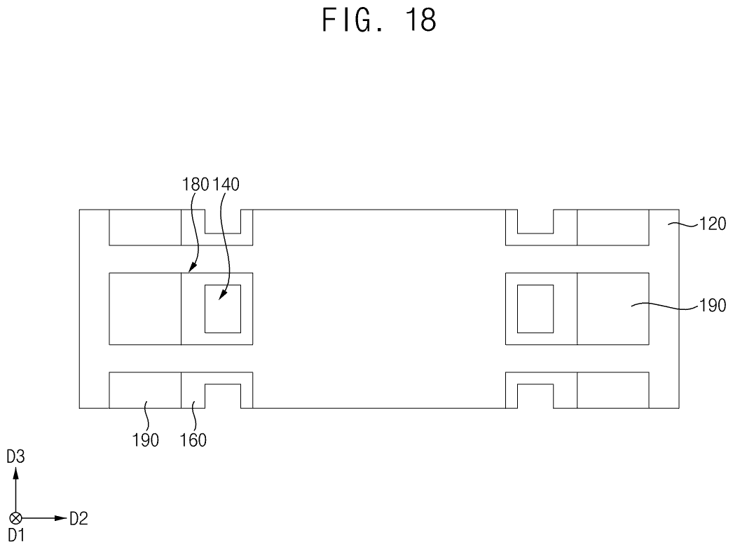

Referring to FIGS. 17 and 18, a first sacrificial insulating interlayer pattern 190 may fill the first hole 130 and a portion of the third hole 180 overlapping the first hole 130 in the first direction D1.

In example embodiments, a first sacrificial insulating interlayer may be formed on the substrate 100 and the mold layer to fill the first to third holes 130, 140 and 180, a planarization process may be performed on the first sacrificial insulating interlayer until the upper surface of the mold layer is exposed, and for example, a dry etching process may be performed on the first sacrificial insulating interlayer to form the first sacrificial insulating interlayer pattern 190.

The first sacrificial insulating interlayer pattern 190 may extend primarily in the first direction D1, and a plurality of first sacrificial insulating interlayer patterns 190 may be spaced apart from each other in the third direction D3 on each of the second portions of the mold layer. The first sacrificial insulating interlayer pattern 190 may include an oxide, e.g., silicon oxide.

As the first insulating interlayer pattern 190 is formed, the second hole 140 and a portion of the third hole 180 not overlapping the first hole 130 in the first direction D1 may remain.

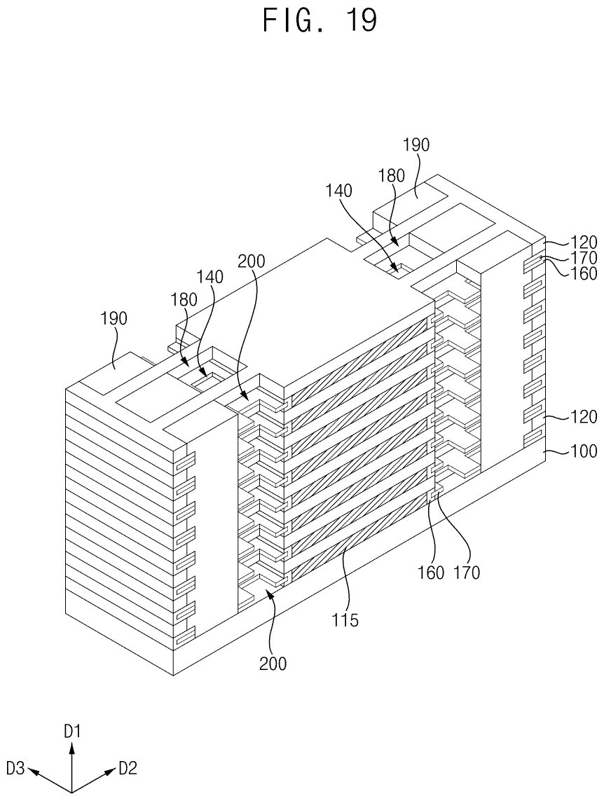

Referring to FIGS. 19 to 21, a portion of the first sacrificial insulation pattern 160 not covered by the first insulating interlayer pattern 190, among a portion of the first sacrificial insulation pattern 160 on each of the second portions of the mold layer, may be removed by an etching process.

In example embodiments, the etching process may include a wet etching process and/or a dry etching process, and a portion of the first sacrificial insulation pattern 160 overlapping the remaining portion of the third hole 180 in the first direction D1 may be removed by the etching process. Thus, a second gap 200 may be formed between each of the second sacrificial insulation patterns 170 and the semiconductor layers 120, and lower and upper surfaces of a portion of each of the semiconductor layers 120 overlapping the remaining portion of the third hole 180 in the first direction D1 may be exposed by the second gap 200.

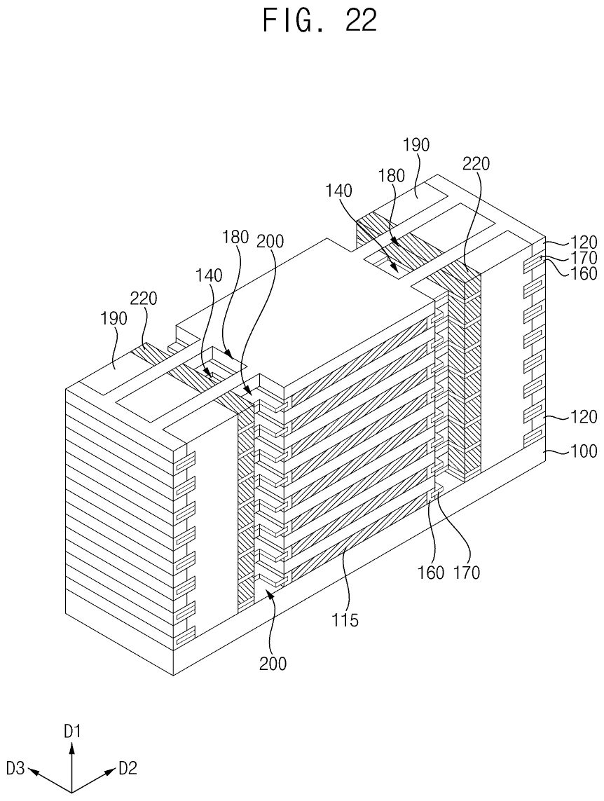

Referring to FIGS. 22 to 24, a gate insulation layer may be formed on inner walls of the second and third holes 140 and 180 and the second gap 200, a gate electrode layer may be formed on the gate insulation layer to fill the second and third holes 140 and 180 and the second gap 200, a planarization process may be performed on the gate electrode layer and the gate insulation layer until the upper surface of the mold layer is exposed, and other portions of the gate electrode layer and the gate insulation layer except for portions of the gate electrode layer and the gate insulation layer adjacent to a first portion of the semiconductor layer 120 between the first sacrificial insulating interlayer patterns 190 in the second direction D2 may be removed by an etching process.

Thus, a gate insulation pattern 210 covering a surface, for example, lower and upper surfaces and opposite sidewalls in the third direction D3 of a second portion of the semiconductor layer 120 adjacent to the first portion of the semiconductor layer 120 in the second direction D2, and a gate electrode 220 covering the gate insulation pattern 210 may be formed.

In example embodiments, a plurality of gate insulation patterns 210 may be spaced apart from each other in the third direction D3 at the level where each of the semiconductor layers 120 is formed at each of the second portions of the mold layer, and a plurality of gate insulation patterns 210 may also be spaced apart from each other in the first direction D1.

A plurality of gate electrodes 220 may be formed at a plurality of levels, respectively, spaced apart from each other in the first direction D1 at each of the second portions of the mold layer. The gate electrode 220 and the gate insulation pattern 210 may collectively form a gate structure 230.

In example embodiments, the gate electrode 220 may extend primarily in the third direction D3 on the first and second regions I and II of the substrate 100 to form a first extension portion 222 (refer to FIGS. 3 and 4), and may extend primarily in the second direction D2 on the second region II of the substrate 100 to form a second extension portion 224 (refer to FIGS. 3 and 4). The first extension portions 222 at the second portions, respectively, of the mold layer may contact the second extension portion 244 on the second region II of the substrate 100.

In example embodiments, the second extension portions 224 of the word lines may be arranged in a stepwise manner in the third direction D3 on the second region II of the substrate 100, and thus lengths in the third direction D3 of the first extension portions 222 of the word lines connected to the second extension portions 224 of the word lines may increase from an uppermost level to a lowermost level in a stepwise manner.

During the etching process, a portion of the second sacrificial insulation pattern 170 not covered by the gate insulation pattern 210 and the gate electrode 220, for example, a portion of the second sacrificial insulation pattern 170 adjacent to the second hole 140 in the third direction D3 may also be removed so that the second gaps 200 over and under, respectively, the second sacrificial insulation pattern 170 may be enlarged in the first direction D1 to be merged to the third gap 205.

Referring to FIG. 25, a second sacrificial insulating interlayer pattern 250 may be formed on the substrate 100 to fill the second and third holes 140 and 180 and the third gap 205 and cover the semiconductor layers 120.

The second sacrificial insulating interlayer pattern 250 may include an oxide, e.g., silicon oxide.

Referring to FIG. 26, a fourth hole 310 may be formed through a central portion in the second direction D2 of the first portion of the mold layer.

The fourth hole 310 may extend primarily in the first direction D1, and may expose an upper surface of the substrate 100.

In example embodiments, the fourth hole 310 may be formed by a dry etching process on the mold layer.

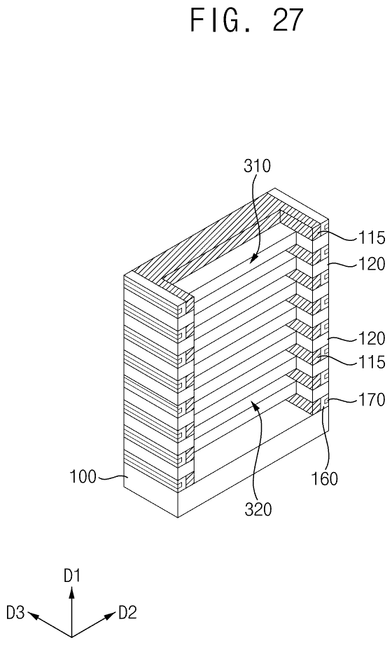

Referring to FIG. 27, a portion of the first sacrificial pattern 115 adjacent to the fourth hole 310 in the third direction D3 may be removed to form a fourth gap 320 between portions of neighboring ones of the semiconductor layers 120 in the first direction D1, which may be adjacent to the fourth hole 310 in the third direction D3.

In example embodiments, a plurality of fourth gaps 320 may be spaced apart from each other in the first direction D1 on the substrate 100, and each of the fourth gaps 320 may be connected to the fourth hole 310. The fourth gap 320 may be formed by a wet etching process and/or a dry etching process on the first sacrificial pattern 115.

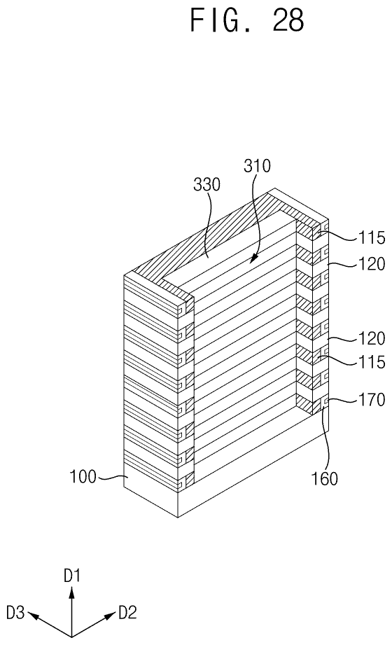

Referring to FIG. 28, a second sacrificial pattern 330 may be formed in the fourth gap 320.

In example embodiments, the second sacrificial pattern 330 may be formed by forming a second sacrificial layer on the substrate 100 to fill the fourth gap 320 and a portion or an entire portion of the fourth hole 310, performing a planarization process on the second sacrificial layer until the upper surface of the mold layer is exposed, and removing a portion of the second sacrificial layer in the fourth hole 310 through, e.g., a dry etching process.

Thus, a plurality of second sacrificial patterns 330 may be spaced apart from each other in the first direction D1 at each of opposite sides in the third direction D3 of the fourth hole 310. The second sacrificial pattern 330 may include an insulating nitride, e.g., silicon nitride.

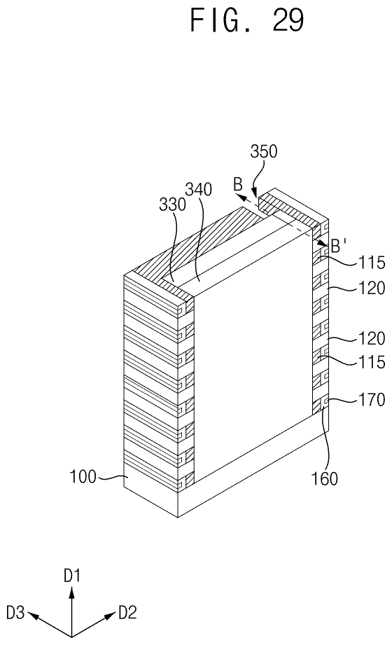

Referring to FIGS. 29 and 30, a third sacrificial insulating interlayer pattern 340 may be formed in the fourth hole 310, and the mold layer may be partially removed by, e.g., a dry etching process to form a fifth hole 350 extending primarily in the first direction D1 and exposing a first end portion in the second direction D2 of a sidewall in the third direction D3 of the second sacrificial pattern 330 not contacting a sidewall of the third sacrificial insulating interlayer pattern 340.

In example embodiments, the third sacrificial insulating interlayer pattern 340 may be formed by forming a third sacrificial insulating interlayer on the substrate 100 to fill the fourth hole 310, and performing a planarization process on the third sacrificial insulating interlayer until the upper surface of the mold layer is exposed. The third sacrificial insulating interlayer pattern 340 may include an oxide, e.g., silicon oxide.

A portion of the semiconductor layer 120 adjacent to the fifth hole 350 in the third direction D3 may be removed by, e.g., a wet etching process to form a fifth gap 355 exposing a sidewall in the third direction D3 of the third sacrificial insulating interlayer pattern 340 between neighboring ones of the first sacrificial patterns 115 in the first direction D1. In example embodiments, a plurality of fifth gaps 355 may be spaced apart from each other in the first direction D1, and each of the fifth gaps 355 may be connected to the fifth hole 350.

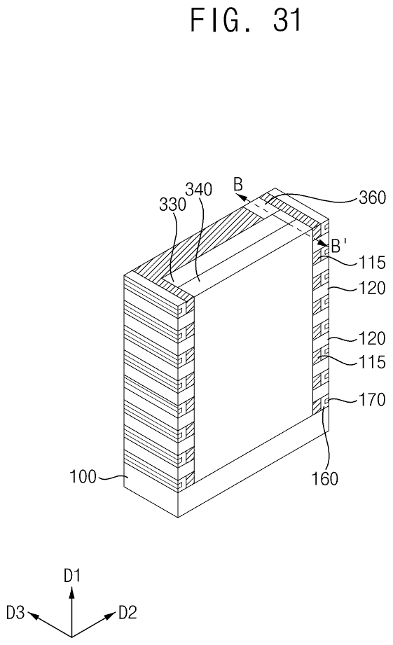

Referring to FIGS. 31 and 32, a fourth sacrificial insulating interlayer pattern 360 may be formed in the fifth hole 350 and the fifth gap 355.

In example embodiments, the fourth sacrificial insulating interlayer pattern 360 may be formed by forming a fourth sacrificial insulating interlayer on the substrate 100 to fill the fifth hole 350 and the fifth gap 355, and performing a planarization process on the fourth sacrificial insulating interlayer until the upper surface of the mold layer is exposed. The fourth sacrificial insulating interlayer pattern 360 may include a material having an etching selectivity with respect to the semiconductor layer 120, the first sacrificial pattern 115, the second sacrificial pattern 330 and the fourth sacrificial insulating interlayer pattern 360.

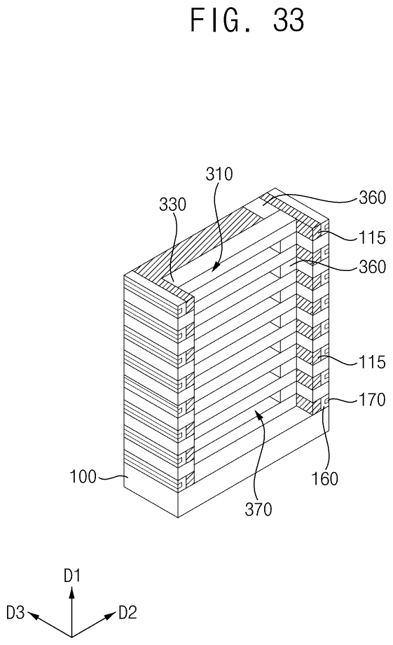

Referring to FIG. 33, the third sacrificial insulating interlayer pattern 340 may be removed by an etching process to form the fourth hole 310 again, and a portion of the semiconductor layer 120 adjacent to the fourth hole 310 in the third direction D3 may be removed to form a sixth gap 370 between neighboring ones of the second sacrificial patterns 330 in the first direction D1. In example embodiments, a plurality of sixth gaps 370 may be spaced apart from each other in the first direction D1, and each of the sixth gaps 370 may be connected to the fourth hole 310.

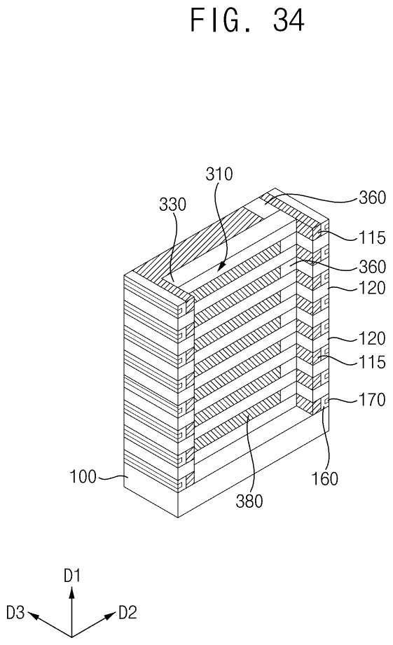

Referring to FIG. 34, a first capacitor electrode 380 may be formed in the sixth gap 370.

In example embodiments, the first capacitor electrode 380 may be formed by forming a first capacitor electrode layer on the substrate 100 to fill the sixth gap 370 and a portion or an entire portion of the fourth hole 310, performing a planarization process on the first capacitor electrode layer until the upper surface of the mold layer is exposed, and removing a portion of the first capacitor electrode layer in the fourth hole through an etching process.

The first capacitor electrode 380 may include an electrically conductive material, e.g., a metal, a metal nitride, a metal silicide, etc.

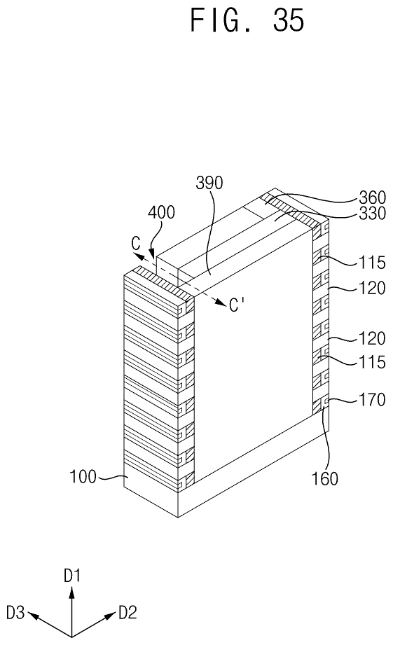

Referring to FIGS. 35 and 36, a fifth sacrificial insulating interlayer pattern 390 may be formed in the fourth hole 310, and the mold layer may be partially removed by, for example, a dry etching process to form a sixth hole 400 extending primarily in the first direction D1 and exposing a second end portion in the second direction D2 of the sidewall in the third direction D3 of the second sacrificial pattern 330 not contacting a sidewall of the fifth sacrificial insulating interlayer pattern 390.

In example embodiments, the fifth sacrificial insulating interlayer pattern 390 may be formed by forming a fifth sacrificial insulating interlayer on the substrate 100 to fill the fourth hole 310, and performing a planarization process on the fifth sacrificial insulating interlayer until the upper surface of the mold layer is exposed. The fifth sacrificial insulating interlayer pattern 390 may include an oxide, e.g., silicon oxide.

A portion of the second sacrificial pattern 300 adjacent to the sixth hole 400 in the third direction D3 may be removed by, e.g., a wet etching process to form a seventh gap 405 exposing a sidewall in the third direction D3 of the fifth sacrificial insulating interlayer pattern 390 between neighboring ones of the first capacitor electrodes 380 in the first direction D1. In example embodiments, a plurality of seventh gaps 405 may be spaced apart from each other in the first direction D1, and each of the seventh gaps 405 may be connected to the sixth hole 400.

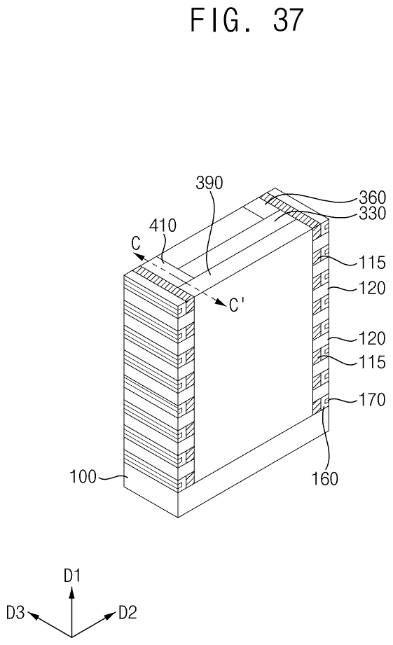

Referring to FIGS. 37 and 38, a sixth sacrificial insulating interlayer pattern 410 may be formed in the sixth hole 400 and the seventh gap 405.

In example embodiments, the sixth sacrificial insulating interlayer pattern 410 may be formed by forming a sixth sacrificial insulating interlayer on the substrate 100 to fill the sixth hole 400 and the seventh gap 405, and performing a planarization process on the sixth sacrificial insulating interlayer until the upper surface of the mold layer is exposed. The sixth sacrificial insulating interlayer pattern 410 may include an oxide, e.g., silicon oxide.

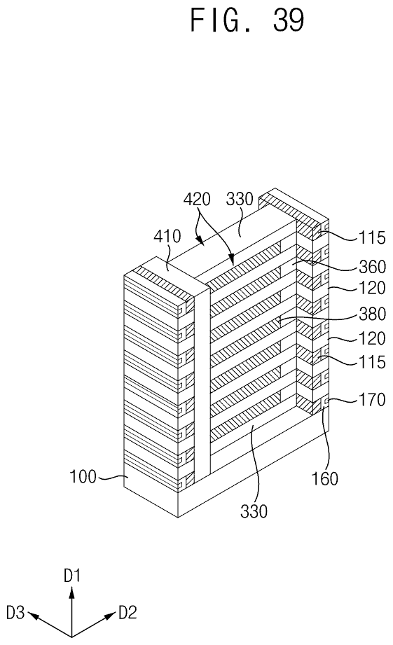

Referring to FIG. 39, a dry etching process may be performed to remove other portions of the fifth sacrificial insulating interlayer pattern 390 except for a portion of the fifth sacrificial insulating interlayer pattern 390 adjacent to the sixth sacrificial insulating interlayer pattern 410 in the third direction D3, and portions of the mold layer and the fourth sacrificial insulating interlayer pattern 360 at a side in the third direction D3 of the second sacrificial pattern 330.

Thus, a seventh hole 420 exposing the upper surface of the substrate 100 may be formed at each of opposite sides of the second sacrificial pattern 330 in the third direction D3. The fourth sacrificial insulating interlayer pattern 360 may remain only at a side of the second sacrificial pattern 330 in the second direction D2, and hereinafter, may be referred to as an insulation pattern 360.

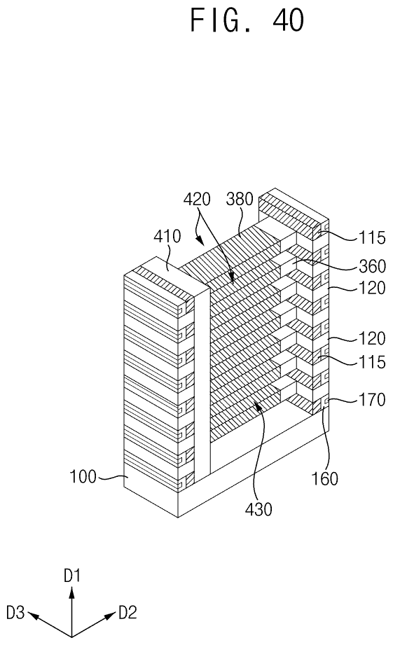

Referring to FIG. 40, the second sacrificial pattern 330 exposed by the seventh hole 420 may be removed by, e.g., a wet etching process.

Thus, an eighth gap 430 may be formed between neighboring ones of the first capacitor electrodes 380 in the first direction D1 and neighboring ones of the fourth sacrificial insulating interlayer patterns 360 in the first direction D1.

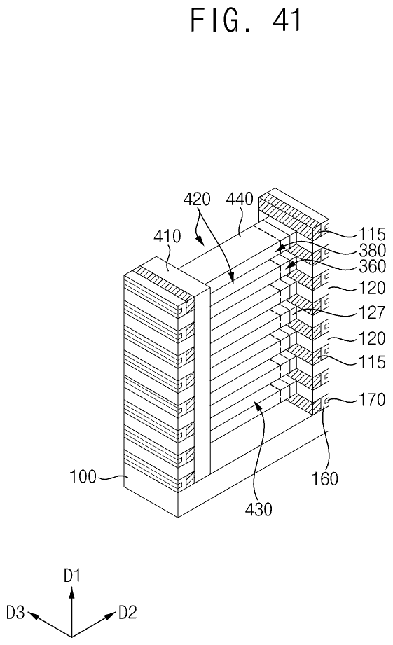

Referring to FIG. 41, a dielectric pattern 440 may be formed on surfaces, for example, lower and upper surfaces and opposite sidewalls in the third direction D3 of the first capacitor electrode 380 and the insulation pattern 360 by a deposition process.

The dielectric pattern 440 may include a metal oxide having a high dielectric constant, e.g., hafnium oxide, zirconium oxide, etc.

A portion of the mold layer adjacent to the seventh hole 420 in the second direction D2 may be removed by an etching process to enlarge the seventh hole 420 in the second direction D2.

In example embodiments, the etching process may include a wet etching process and/or a dry etching process. As the etching process is performed, a connection pattern 127 may be formed at a sidewall in the second direction D2 of each of the insulation pattern 360 and the dielectric pattern 440. Impurities may be doped into the connection pattern 127 by, e.g., a slope ion implantation process, and thus the connection pattern 127 may include a semiconductor material doped with impurities.

In an example embodiment, a thickness and a width in the first and third directions D1 and D3, respectively, of the connection pattern 127 may be substantially the same as a thickness and a width in the first and third directions D1 and D3, respectively, of a structure including the insulation pattern 360 and the dielectric pattern 440, however, the inventive concept is not necessarily limited thereto.

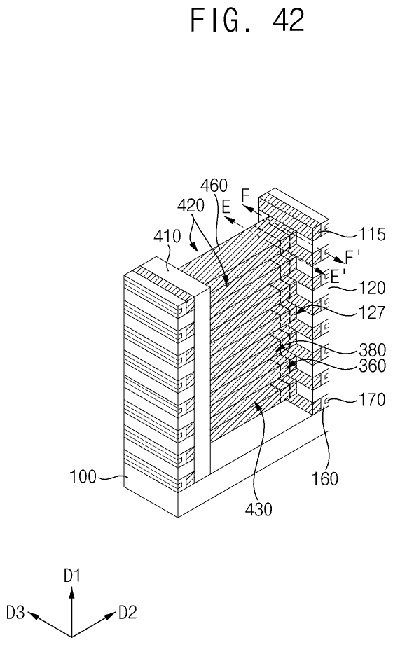

Referring to FIGS. 42 to 44, a second capacitor electrode 460 may cover surfaces, for example, lower and upper surfaces and opposite sidewalls in the third direction D3 of the dielectric pattern 440 and the connection pattern 127 by a deposition process.

The second capacitor electrode 460 may include an electrically conductive material, e.g., a metal, a metal nitride, a metal silicide, doped silicon-germanium, etc.

The first capacitor electrode 380, the dielectric pattern 440 and the second capacitor electrode 460 sequentially stacked may form a capacitor 470.

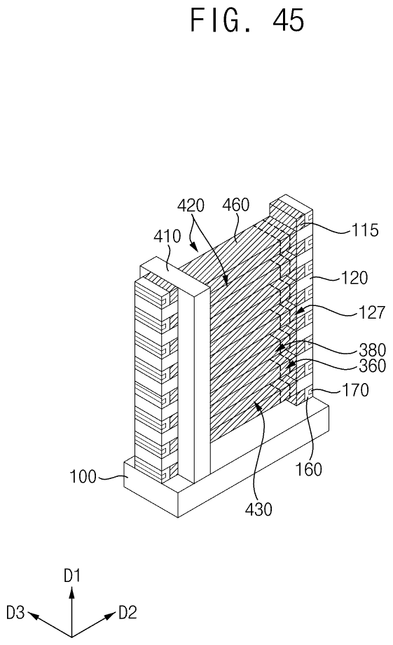

Referring to FIG. 45, for example, a dry etching process may be performed to partially remove the mold layer and the first and second sacrificial insulation patterns 160 and 170.

In an example embodiment, a thickness and a width in the first and third directions D1 and D3, respectively, of the first sacrificial pattern 115 and the semiconductor layer 120 included in the first portion of the mold layer at each of opposite sides in the second direction D2 of the capacitor 470 may be substantially the same as a thickness and a width in the first and third directions D1 and D3, respectively, of the first capacitor electrode 380 included in the capacitor 470, however, the inventive concept is not necessarily limited thereto, and for example, may be substantially the same as a thickness and a width in the first and third directions D1 and D3, respectively, of the capacitor 470.

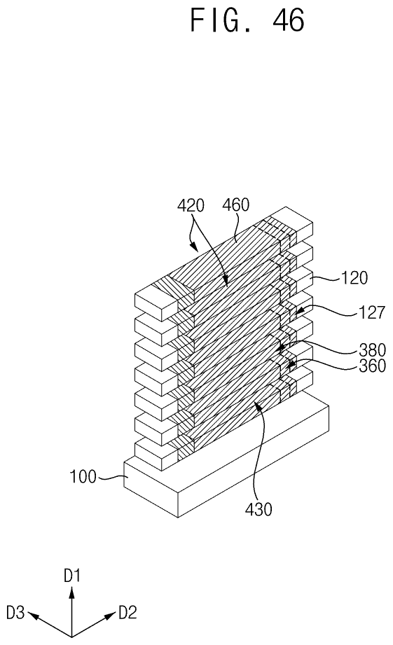

Referring to FIG. 46, the first sacrificial patterns 115 and the sixth sacrificial insulating interlayer pattern 410 may be removed by, e.g., a wet etching process so that the semiconductor layer 120 may remain at each of opposite sides in the second direction D2 of the capacitor 470.

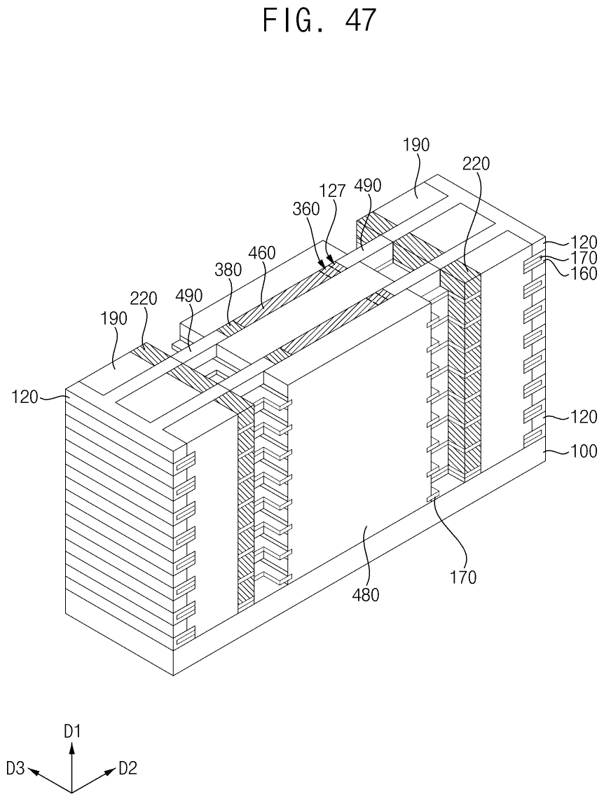

Referring to FIG. 47, a seventh sacrificial insulating interlayer pattern 480 may be formed on the substrate 100 to cover the capacitors 470, the second sacrificial insulating interlayer pattern 250 may be removed, and second impurity regions 490 may be formed at respective portions of the semiconductor layer 120 adjacent to each of the capacitors 470 in the second direction D2 by, e.g., a slope ion implantation process.

In example embodiments, a plurality of second impurity regions 490 may be spaced apart from each other in the first and third directions D1 and D3 at each of opposite sides in the second direction D2 of each of the capacitors 470.

The seventh sacrificial insulating interlayer pattern 480 may include an oxide, e.g., silicon oxide.

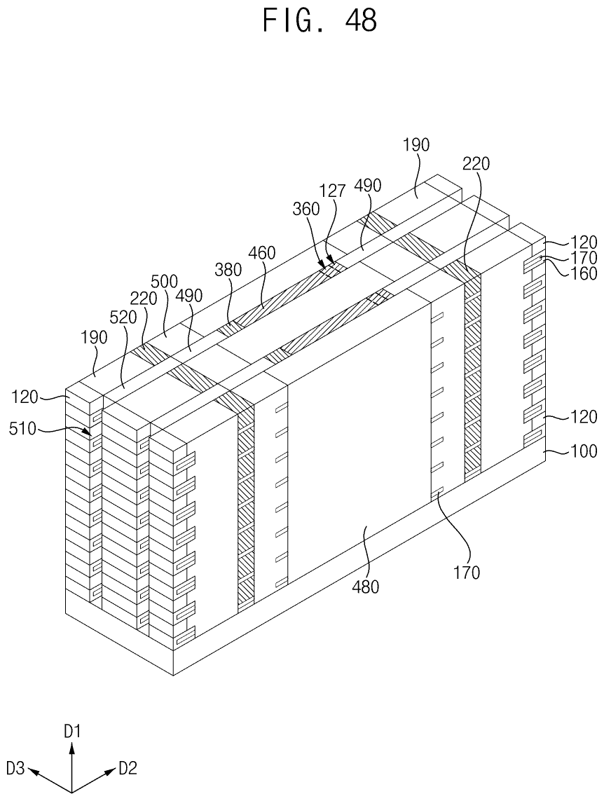

Referring to FIG. 48, an eighth sacrificial insulating interlayer pattern 500 may be formed on the substrate 100 to cover the second impurity regions 490, and for example, a dry etching process may be performed on each of the second portions of the mold layer to form an eighth hole 510 exposing the upper surface of the substrate 100.

In example embodiments, the eighth hole 510 may expose sidewalls in the second direction D2 of the semiconductor layers 120 between the first sacrificial insulating interlayer patterns 190, and sidewalls in the second direction D2 of portions of the first and second sacrificial insulation patterns 160 and 170 between neighboring ones of the semiconductor layers 120 in the first direction D1. Thus, the eighth hole 510 may extend at each of the second portions of the mold layer, and a plurality of eighth holes 510 may be spaced apart from each other in the third direction D3.

First impurity regions 520 may be formed in respective portions of the semiconductor layers 120 exposed by the eighth hole 510 through, e.g., a slope ion implantation process. In example embodiments, a plurality of first impurity regions 520 may be spaced apart from each other in the first and third directions D1 and D3 at each of the second portions of the mold layer.

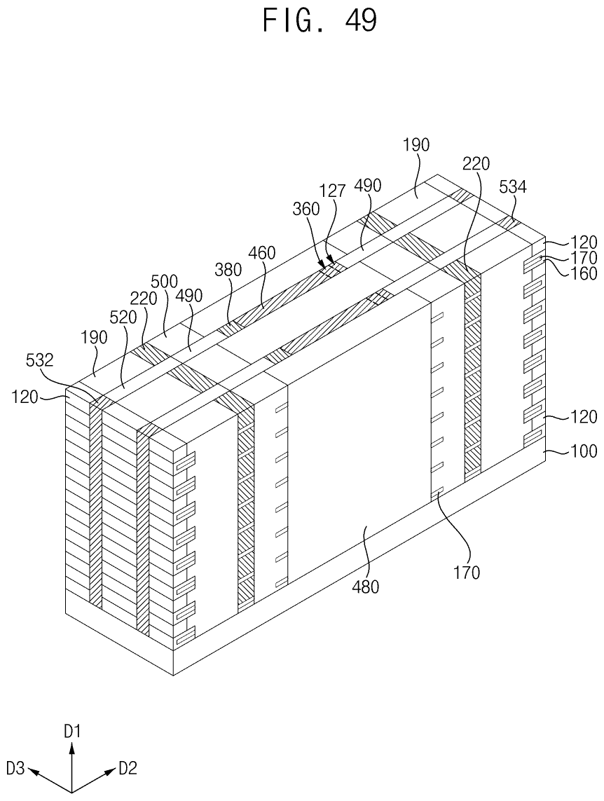

Referring to FIG. 49, first and second bit lines 532 and 534 may be formed in the eighth hole 510.

The first and second bit lines 532 and 534 may be formed by forming a bit line layer on the substrate 100, the mold layer, the first, seventh and eighth sacrificial insulating interlayer patterns 190, 480 and 500, the gate structure 230, the capacitor 470 and the first and second impurity regions 520 and 490, and performing a planarization process on the bit line layer until the upper surface of the mold layer is exposed.

In example embodiments, each of the first and second bit lines 532 and 534 may extend primarily in the first direction D1 at each of the second portions of the mold layer, and a plurality of first bit lines 532 may be spaced apart from each other in the third direction D3 and a plurality of second bit lines 534 may be spaced apart from in the third direction D3.

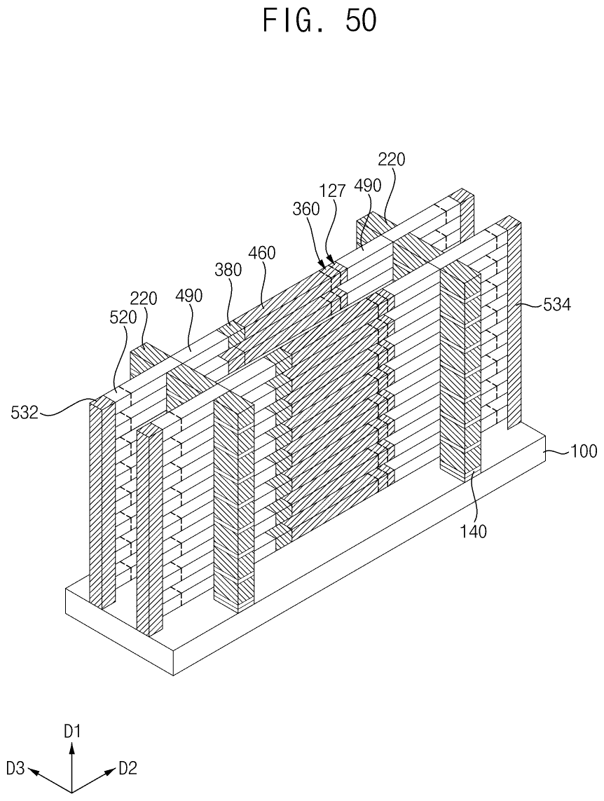

Referring to FIGS. 50 to 52, a portion of the mold layer disposed between the first and second bit lines 532 and 534, the first and second sacrificial insulation patterns 160 and 170, and the first, seventh and eighth sacrificial insulating interlayer patterns 190, 480 and 500 may be removed by, e.g., a wet etching process and/or a dry etching process, and a portion of the semiconductor layer 120 in the mold layer surrounded by the gate structure 230 may remain as a channel 125.

Thus, the capacitor 470 including the first and second capacitor electrodes 380 and 460 and the dielectric pattern 440, the second impurity region 490, the channel 125 and the first impurity region 520 sequentially disposed at each of opposite sides of the capacitor 470 in the second direction D2, the gate structure 230 surrounding the channel 125 and extending primarily in the third direction D3, and the first and second bit lines 532 and 534 contacting sidewalls of the first impurity regions, respectively, and extending primarily in the first direction D1 may be formed on the substrate 100.

The gate structure 230 and the first and second impurity regions 520 and 490 at respective opposite sides of the gate structure 230 in the second direction D2 may form a transistor, and each of the first and second impurity regions 520 and 490 may serve as a source/drain of the transistor. Thus, the first and second impurity regions 520 and 490 may also be referred to as first and second source/drain layers 520 and 490, respectively.

Referring to FIGS. 3 to 7 again, contact plugs 600 may contact upper surfaces of the second extension portions of the word lines to complete the fabrication of the semiconductor device.

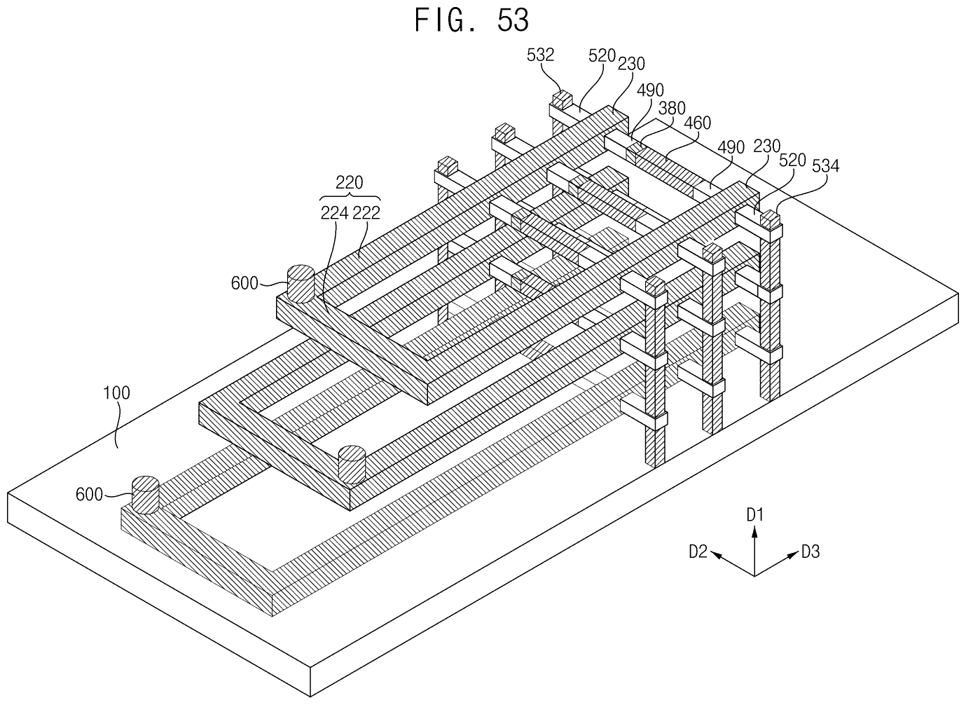

FIG. 53 is a perspective view illustrating a semiconductor device in accordance with example embodiments. This semiconductor device may be substantially the same as or similar to that of FIGS. 3 to 7 except for some elements, and thus to the extent that an element is not described in detail with respect to this figure, it may be understood that the element is at least similar to a corresponding element that has been described elsewhere within the present disclosure.

Referring to FIG. 53, the first source/drain layer 520 may surround an entire sidewall of each of the first and second bit lines 532 and 534, instead of contacting only a sidewall in the second direction D2 of each of the first and second bit lines 532 and 534.

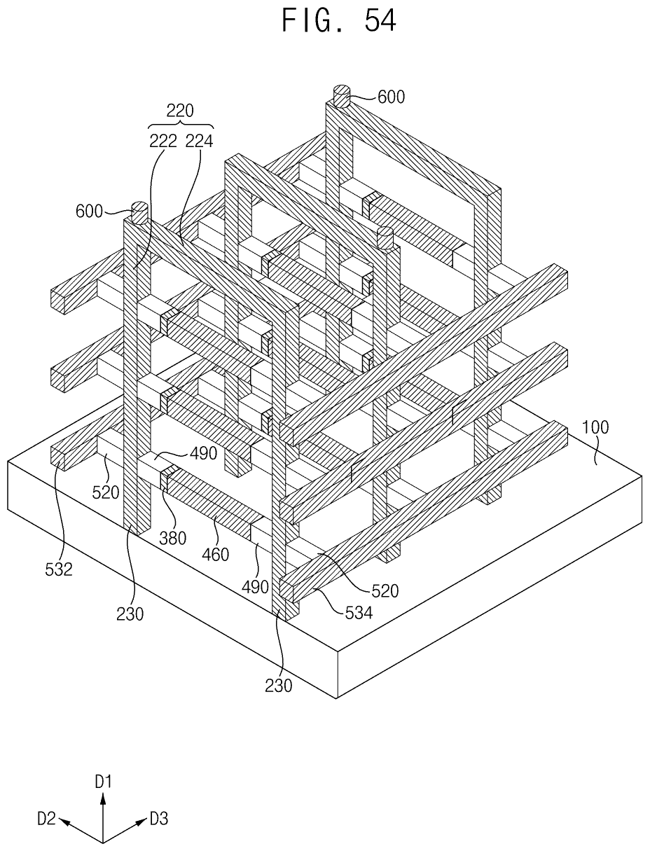

FIG. 54 is a perspective view illustrating a semiconductor device in accordance with example embodiments. This semiconductor device may be substantially the same as or similar to that of FIGS. 3 to 7 or FIG. 53 except for some elements, and thus to the extent that an element is not described in detail with respect to this figure, it may be understood that the element is at least similar to a corresponding element that has been described elsewhere within the present disclosure.

Referring to FIG. 54, each of the first and second bit lines 532 and 534 may extend primarily in the third direction D3 substantially parallel to the upper surface of the substrate 100, instead of extending primarily in the first direction D1 substantially perpendicular to the upper surface of the substrate 100.

In example embodiments, a plurality of first bit lines 532 may be spaced apart from each other in the first direction D1, and a plurality of second bit lines 534 may be spaced apart from each other in the first direction D1. Additionally, the first and second bit lines 532 and 534 may be spaced apart from each other in the second direction D2.

The word line may include the first extension portions 222 extending primarily in the first direction D1 and the second extension portion 224 extending primarily in the second direction D2, and the first extension portions may contact the second extension portion 224 so as to be electrically connected to each other.

In example embodiments, a plurality of word lines may be spaced apart from each other in the third direction D3, and lengths in the first direction D1 of the first extension portions 222 of the word lines, respectively, may be substantially the same as each other and heights of upper surfaces of the second extension portions 224 of the word lines, respectively, may be substantially the same as each other.

The contact plugs 600 may be disposed on the upper surfaces of the second extension portions of the word lines, and may be arranged in a zigzag pattern in a plan view.

While the present inventive concepts have been shown and described with reference to example embodiments thereof, it will be understood by those of ordinary skill in the art that various changes in form and details may be made thereto without departing from the spirit and scope of the present inventive concepts.

What is claimed is:

1. A semiconductor device, comprising:
first and second bit lines each disposed on a substrate, each of the first and second bit lines extending primarily in a first direction that is perpendicular to an upper surface of the substrate, and the first and second bit lines being spaced apart from each other in a second direction that is parallel to the upper surface of the substrate;
a word line including:
first extension portions disposed between the first and second bit lines, each of the first extension portions extending primarily in a third direction that is parallel to the upper surface of the substrate and intersecting the second direction; and
a second extension portion extending primarily in the second direction at a same level as the first extension portions and being connected to the first extension portions;
first and second channels each extending through the first extension portions of the word line; and
a capacitor including:
a first capacitor electrode electrically connected to the first channel;
a dielectric pattern disposed on a surface of the first capacitor electrode; and
a second capacitor electrode disposed on a surface of the dielectric pattern, the second capacitor electrode being electrically connected to the second channel.

2. The semiconductor device according to claim 1, further comprising:
a first source/drain layer disposed between and contacting both the first bit line and the first channel; and
a second source/drain layer disposed between and contacting both the first channel and the first capacitor electrode.

3. The semiconductor device according to claim 1, further comprising:
a first source/drain layer disposed between and contacting both the second bit line and second first channel; and
a second source/drain layer disposed between the second channel and the second capacitor electrode.

4. The semiconductor device according to claim 3, further comprising a connection pattern disposed between the second capacitor electrode and the second source/drain layer.

5. The semiconductor device according to claim 4, wherein the second capacitor electrode covers a surface of the connection pattern.

6. The semiconductor device according to claim 3, further comprising an insulation pattern disposed between the first capacitor electrode and the second source/drain layer.

7. The semiconductor device according to claim 6, wherein the dielectric pattern covers a surface of the insulation pattern.

8. The semiconductor device according to claim 1, wherein the first and second channels surround sidewalls of the first and second bit lines, respectively.

9. The semiconductor device according to claim 1, wherein a portion of each of the first extension portions of the word line surrounding each of the first and second channels defines a gate electrode, and
wherein the semiconductor device further comprises a gate insulation pattern covering lower and upper surfaces and opposite sidewalls in the third direction of each of the first and second channels and contacting the gate electrode.

10. The semiconductor device according to claim 1, further comprising:
a plurality of word lines that are spaced apart from each other in the first direction, the word line being one of the plurality of word lines;
a plurality of first channels spaced apart from each other in the first direction, the first channel being one of the plurality of first channels;
a plurality of second channels spaced apart from each other in the first direction, the second channel being one of the plurality of second channels; and
a plurality of capacitors spaced apart from each other in the first direction, the capacitor being one of the plurality of capacitors.

11. The semiconductor device according to claim 10, wherein lengths in the third direction of the first extension portions of the plurality of word lines, respectively, increase or decrease from an uppermost level to a lowermost level in a stepwise manner.

12. The semiconductor device according to claim 10, wherein the second extension portions of the plurality of word lines, respectively, are arranged in the third direction in a stepwise manner.

13. The semiconductor device according to claim 1, further comprising:
a plurality of first bit lines that are spaced apart from each other in the third direction, the first bit line being one of the plurality of first bit lines;
a plurality of second bit lines that are spaced apart from each other in the third direction, the second bit line being one of the plurality of second bit lines;
a plurality of first channels spaced apart from each other in the third direction, the first channel being one of the plurality of first channels;
a plurality of second channels spaced apart from each other in the third direction, the second channel being one of the plurality of second channels; and
a plurality of capacitors spaced apart from each other in the third direction, the capacitor being one of the plurality of capacitors, and
wherein the plurality of first channels extend through a first one of the first extension portions of the word line, and the plurality of second channels extend through a second one of the first extension portions of the word line.

14. A semiconductor device, comprising:
bit lines disposed on a substrate, each of the bit lines extending primarily in a first direction, and the bit lines being spaced apart from each other in a second direction that is perpendicular to the first direction;
a first transistor, a capacitor and a second transistor sequentially disposed in the second direction between the bit lines; and
a word line including:
first extension portions electrically connected to the first and second transistor, respectively, each of the first extension portions extending primarily in a third direction that is perpendicular to the first and second directions; and
a second extension portion extending primarily in the second direction and being connected to the first extension portions,
wherein each of the first and second transistors includes:
a gate electrode electrically connected to each of the first extension portions of the word line;
a channel electrically connected to the gate electrode; and
first and second source/drain layers disposed at opposite sides, respectively, of the channel in the second direction,
wherein the capacitor includes a first capacitor electrode, a dielectric pattern and a second capacitor electrode sequentially stacked, and
wherein the first source/drain layers of the first and second transistors, respectively, are electrically connected to the bit lines, respectively, and the second source/drain layers of the first and second transistors, respectively, are electrically connected to the first and second capacitor electrodes, respectively.

15. The semiconductor device according to claim 14, wherein the first direction is perpendicular to an upper surface of the substrate, and the second and third directions are parallel to the upper surface of the substrate.

16. The semiconductor device according to claim 15, further comprising a plurality of word lines that are spaced apart from each other in the first direction, the word line being one of the plurality of word lines,
wherein lengths in the third direction of the first extension portions of the plurality of word lines, respectively, increase or decrease from an uppermost level to a lowermost level in a stepwise manner.

17. The semiconductor device according to claim 14, wherein the third direction is perpendicular to an upper surface of the substrate, and the first and second directions are parallel to the upper surface of the substrate.

18. The semiconductor device according to claim 17, further comprising a plurality of word lines that are spaced apart from each other in the first direction, the word line being one of the plurality of word lines,
wherein lengths in the third direction of the first extension portions of the plurality of word lines, respectively, are substantially the same as each other.

19. A semiconductor device, comprising:
first and second bit lines on a substrate, each of the first and second bit lines extending primarily in a first direction that is perpendicular to an upper surface of the substrate, and the first and second bit lines being spaced apart from each other in a second direction that is parallel to the upper surface of the substrate;
a word line including:
first extension portions between the first and second bit lines, each of the first extension portions extending primarily in a third direction that is parallel to the upper surface of the substrate and intersecting the second direction; and
a second extension portion extending primarily in the second direction at the same level as the first extension portions and being connected to the first extension portions;
first and second channels each extending through the first extension portions of the word line;
a first source/drain layer disposed between and contacting both the first bit line and the first channel;
a second source/drain layer disposed between and contacting both the second bit line and the second channel;
a capacitor including:
a first capacitor electrode contacting the first source/drain layer;
a dielectric pattern disposed on a surface of the first capacitor electrode; and
a second capacitor electrode disposed on a surface of the dielectric pattern;
a third source/drain layer disposed between and contacting both the first channel and the first capacitor electrode;
a fourth source/drain layer disposed between the second channel and the second capacitor electrode;
a connection pattern contacting both the second capacitor electrode and the second source/drain layer; and
an insulation pattern disposed between the first capacitor electrode and the connection pattern.

20. The semiconductor device according to claim 19, further comprising:
a plurality of word lines that are spaced apart from each other in the first direction, the word line being one of the plurality of word lines;
a plurality of first channels spaced apart from each other in the first direction, the first channel being one of the plurality of first channels;
a plurality of second channels spaced apart from each other in the first direction, the second channel being one of the plurality of second channels; and
a plurality of capacitors spaced apart from each other in the first direction, the capacitor being one of the plurality of capacitors,
wherein lengths in the third direction of the first extension portions of the plurality of word lines, respectively, increase or decrease from an uppermost level to a lowermost level in a stepwise manner, and
wherein the second extension portions of the plurality of word lines, respectively, are arranged in the third direction in a stepwise manner.
